(19) United States
(12) Patent Application Publication
(10) Pub. No.: US 2024/0049494 A1
(43) Pub. Date: Feb. 8, 2024

(54) MIXTURES AND USES THEREOF IN OPTOELECTRONIC FIELD

(71) Applicant: Zhejiang Brilliant Optoelectronic Technology Co.,Ltd., Taizhou (CN)

(72) Inventors: Junyou PAN, Taizhou (CN); Juye ZHU, Taizhou (CN); Jiahui TAN, Taizhou (CN)

(73) Assignee: Zhejiang Brilliant Optoelectronic Technology Co.,Ltd., Taizhou (CN)

(21) Appl. No.: 18/483,380

(22) Filed: Oct. 9, 2023

Related U.S. Application Data
(63) Continuation of application No. PCT/CN2022/085578, filed on Apr. 7, 2022.

(30) Foreign Application Priority Data
Apr. 7, 2021 (CN) 202110370819.7

(51) Int. Cl. H10K 50/115; H10K 85/10; H10K 85/60

(52) U.S. Cl. CPC H10K 50/115; H10K 85/10; H10K 85/6574; H10K 85/622; H10K 85/6576; H10K 85/6572; H10K 85/633; H10K 85/658

(57) ABSTRACT

Disclosed are mixtures including an organic compound H, an inorganic nanoemitter E, and at least one organic resin. Also provided are formulations containing the mixtures and at least one solvent. Further provided are organic light-emitting devices containing the mixtures.

### CROSS-REFERENCE TO RELATED APPLICATIONS

The present application is a continuation of International Application No. PCT/CN2022/085578, filed on Apr. 7, 2022, which claims priority to Chinese Patent Application No. 202110370819.7, filed on Apr. 7, 2021. All of the aforementioned applications are incorporated herein by reference in their entireties.

### TECHNICAL FIELD

The present disclosure relates to the field of organic electronic material and device technology, and in particularly to a mixture, a formulation, an organic light-emitting device, and the applications thereof in the optoelectronic field.

### BACKGROUND

According to the principles of colorimetry, the narrower the full width at half maximum (FWHM) of the lights perceived by the human eyes is, the higher the color purity, and the more vivid the color display would be. Display devices with narrow-FWHM red, green and blue primary light are able to show vivid views with high color gamut and high visual quality.

The current mainstream full-color displays are achieved mainly in two ways. The first method is to actively emit red, green and blue lights, typically such as RGB-OLED display. The current mature technology is to fabricate light-emitting devices with three colors by vacuum evaporation with fine metal masks, which is complex, at high cost and difficult to achieve high-resolution display over 600 ppi. The second method is using color converters to convert the single-color light from the light-emitting devices into different colors, thereby achieving a full-color display. For example, Samsung combines blue OLEDs with red and green quantum dots (QD) films as the color converters. In this case, the fabrication of the light emitting devices is much simpler, and thus higher yield. Furthermore, the manufacture of the color converters can be achieved by different technologies, such as vacuum evaporation, ink-jet printing, transfer printing, photolithography, etc., appliable to a variety of display products with very different resolution requirements from low resolution large-size TV (around only 50ppi) to high resolution silicon-based micro-display (over 3000 ppi).

Currently, the most promising color conversion materials for use in color converters are inorganic nanocrystals, commonly known as quantum dots, which are nanoparticles (especially quantum dots) of an inorganic semiconductor material (InP, CdSe, CdS, ZnSe, etc.) with a diameter of 2 nm to 8 nm. Limited by the current synthesis and separation technology of quantum dots, the FWHMs of CD-containing quantum dots typically range from 25 nm to 40 nm, which meet the display requirements of NTSC for color purity. Meanwhile, Cd-free quantum dots generally come with larger FWHMs of 35 nm to 75 nm. In addition, the extinction coefficient is generally low, requiring thicker films, the typical 10 μm or more is needed to achieve complete absorption of blue light, which is a great challenge for mass production processes, especially for Samsung's technology of combing blue OLED with red-green quantum dots.

Therefore, from the industrial perspective, it is urgent to find a material for the color converter that maintains the characteristics of the narrow emission spectrum of the quantum dot while reducing the thickness of the film.

### SUMMARY

In one aspect, the present disclosure provides a mixture comprising an organic compound H, an inorganic nanoemitter E, and at least one organic resin, where 1) the emission spectrum of the organic compound H is on the short wavelength side of the absorption spectrum of the inorganic nanoemitter E, and at least partially overlaps with the absorption spectrum of the inorganic nanoemitter E; 2) the FWHM of the emission spectrum of the inorganic nanoemitter E≤45 nm.

In addition or alternatively, the inorganic nanoemitter E of the mixture is selected from a colloidal quantum dot or a nanorod with a single distribution.

In addition or alternatively, the inorganic nanoemitter E of the mixture comprises a semiconductor material, selecting from CdSe, CdS, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AN, AlAs, AlSb, CdSeTe, ZnCdSe, PbSe, PbTe, PbS, PbSnTe, Tl₂SnTes, or any combination thereof.

In another aspect, the present disclosure also provides a formulation comprising a mixture as described herein and at least one solvent.

In yet another aspect, the present disclosure further provides an organic functional film comprising a mixture as described herein.

In yet another aspect, the present disclosure further provides an optoelectronic device comprising a mixture or an organic functional film as described herein.

In yet another aspect, the present disclosure further provides an organic light-emitting device comprising a substrate, a first electrode, an organic light-emitting layer, a second electrode, a color conversion layer, and an encapsulation layer in sequence from bottom to top, the second electrode is at least partially transparent, where 1) the color conversion layer comprises the mixture as described herein; 2) the color conversion layer absorbs 50% or more of the light emitted by the organic light-emitting layer through the second electrode; 3) the emission spectrum of the organic compound H is on the short wavelength side of the absorption spectrum of the inorganic nanoemitter E, and at least partially overlaps with the absorption spectrum of the inorganic nanoemitter E; 4) the FWHM of the emission spectrum of the inorganic nanoemitter E≤45 nm.

Beneficial effect: in the mixture as described herein, the organic compound H has a relatively high extinction coefficient, the inorganic nanoemitter E has a relatively high luminescence efficiency and narrow emission FWHM. Moreover, the energy transfer efficiency between the organic compound H and the inorganic nanoemitter E is high, thereby optimizing separately the absorption and luminescence functions, and facilitating the preparation of a high-efficiency color converter with a thin thickness, meeting the requirements of high color gamut displays. Furthermore, the organic compound H can be selected from the compounds easy to synthesize. Due to the high proportion of the organic compound H in the formulation, the cost could be greatly reduced.

### BRIEF DESCRIPTION OF THE DRAWINGS

FIG. 1 is a schematic view of a red, green and blue (RGB) three-color display device.

### DETAILED DESCRIPTION OF THE EMBODIMENTS

The present disclosure provides a mixture, a formulation, an organic light-emitting device, and the applications thereof in the optoelectronic field.

In order to facilitate understanding of the present disclosure, the present disclosure will be described in detail below with reference to the accompanying drawings, in which the preferred embodiments of the present disclosure are shown. The present disclosure may be embodied in many different forms and is not limited to the embodiments described herein. Rather, these embodiments are provided so that the understanding of the invention of the present disclosure will be more thorough.

Unless otherwise defined, all technical and scientific terms used herein have the same meaning as commonly understood by one of ordinary skill in the art belonging to the present disclosure. The terms used herein in the description of the present disclosure are used only for the purpose of describing specific embodiments and are not intended to be limiting of the present disclosure. As used herein, the term “and/or” includes any and all combinations of one or more of the relevant listed items.

As used herein, the terms “host material”, “matrix material” have the same meaning, and they are interchangeable with each other.

As used herein, the terms “formulation”, “printing ink”, and “ink” have the same meaning, and they are interchangeable with each other.

In one aspect, the present disclosure provides a mixture comprising an organic compound H, an inorganic nanoemitter E, and at least one organic resin, where 1) the emission spectrum of the organic compound H is on the short wavelength side of the absorption spectrum of the inorganic nanoemitter E, and at least partially overlaps with the absorption spectrum of the inorganic nanoemitter E; 2) the FWHM of the emission spectrum of the inorganic nanoemitter E≤45 nm.

In some embodiments, the FWHM of the emission spectrum of the inorganic nanoemitter E≤45 nm, preferably ≤40 nm, more preferably ≤35 nm, further preferably ≤30 nm, and most preferably ≤25 nm.

In some embodiments, the photoluminescence quantum efficiency (PLQY) of the inorganic nanoemitter E≥60%, preferably ≥65%, more preferably ≥70%, and most preferably ≥80%.

In some embodiments, the inorganic nanoemitter E is selected from a luminescent semiconductor nanocrystal, a perovskite quantum dot, or a metal nanocluster.

In some embodiments, the inorganic nanoemitter E is a luminescent semiconductor nanocrystal.

In some embodiments, the average particle size of the luminescent semiconductor nanocrystal is in the range of 1 nm to 1000 nm. In some embodiments, the average particle size of the luminescent semiconductor nanocrystal is in the range of 1 nm to 100 nm. In some embodiments, the average particle size of the luminescent semiconductor nanocrystal is in the range of 1 nm to 20 nm, preferably in the range of 1 nm to 10 nm.

The semiconductor forming the luminescent semiconductor nanocrystals may comprise a Group IV element, a Group II-VI compound, a Group II-V compound, a Group III-VI compound, a Group III-V compound, a Group IV-VI compound, a Group compound, a Group II-IV-VI compound, a Group II-IV-V compound, an alloy including any of the foregoing, and/or a mixture including any of the foregoing, including ternary and quaternary mixtures or alloys. A non-limiting list of examples includes ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TiN, TiP, TiAs, TiSb, PbO, PbS, PbSe, PbTe, Ge, Si, an alloy including any of the foregoing, and/or a mixture including any of the foregoing, including ternary and quaternary mixtures or alloys.

In some embodiments, the luminescent semiconductor nanocrystal comprises a II-VI semiconductor material, which is preferably selected from CdSe, CdS, CdTe, ZnO, ZnSe, ZnS, ZnTe, HgS, HgSe, HgTe, CdZnSe, or any combination thereof. In some embodiments, CdSe is used for visible-inorganic nanoemitter due to the relatively mature synthesis.

In some embodiments, the luminescent semiconductor nanocrystal comprises a III-V semiconductor material, which is preferably selected from InAs, InP, InN, GaN, InSb, InAsP, InGaAs, GaAs, GaP, GaSb, AlP, AN, AlAs, AlSb, CdSeTe, ZnCdSe, or any combination thereof.

In some embodiments, the luminescent semiconductor nanocrystal comprises a IV-VI semiconductor material, which is preferably selected from PbSe, PbTe, PbS, PbSnTe, Tl₂SnTe₅, or any combination thereof.

In some embodiments, the inorganic nanoemitter E is selected from a colloidal quantum dot or a nanorod with a single distribution.

The shapes of semiconductor nanocrystals and other nanoparticles may include spheres, rods, disks, crosses, T-shapes, other shapes, or mixtures thereof. There are various methods for fabricating semiconductor nanocrystals, and a preferred method is a solution-phase colloidal method for controlling growth. Details of this method can be found in Alivisatos, A. P, Science 1996, 271, p933; X. Peng et al, J. Am. Chem. Soc. 1997, 119, p7019; and C. B. Murray et al. J. Am. Chem. Soc. 1993, 115, p8706. The contents of the documents listed herein above are incorporated herein by reference. In these methods, the organometallic precursor (comprises a M donor and a X donor, as follows) pyrolyzing at high temperature is rapidly injected into a hot solution containing a surfactant (coordinating solvent). These precursors split at high temperature and react to become nanocrystalline nucleis. After this initial discrete nucleation stage, the growth stage is initiated by adding monomers to the growing crystals. The products are free-standing crystalline nanoparticles in solution with organic surfactant molecules encapsulating their surfaces. This synthetic method involves initial discrete nucleation in seconds, followed by crystal growth at high temperature for several minutes. The nature and course of the reaction can be altered by varying parameters such as temperature, type of surfactant, amount of precursor, and ratio of surfactant to monomer. In addition, the temperature controls the nucleation process, the precursor decomposition rate, and the growth rate. The organic surfactant molecule regulates solubility and controls nanocrystal shape. The ratios of surfactants to monomers, surfactants to each other, monomers to each other, as well as the concentration of each monomer strongly influence the crystallite growth kinetics. By properly controlling the reaction parameters, the distribution of the obtained semiconductor nanocrystals is very narrow, i.e., the particle size of the monodisperse distribution. Thus the diameter of the monodisperse distribution can also be used as a measure of the crystallite size. As used herein, a monodisperse population of crystallites includes a population of particles where at least about 60% of the particles in the population fall within a specified particle size range. A preferred monodisperse crystal has a deviation diameter <15% rms, preferably <10% rms, and most preferably <5% rms. The terms “monodisperse nanocrystal”, “nanodot”, and “quantum dot” are readily understood by those of ordinary skill in the art to denote the same structural bodies, and they are interchangeable with each other in the present disclosure.

In some embodiments, the luminescent semiconductor nanocrystal or the quantum dot comprises a core containing a first semiconductor material and a shell containing a second semiconductor material, where the shell is deposited over at least a portion of the core surface. A semiconductor nanocrystal comprising a core and a shell is also referred to as a “core/shell” semiconductor nanocrystal or a quantum dot.

In the semiconductor nanocrystals, the light emission is generated by the band-edge state of the nanocrystal. The band-edge emission from the luminescent nanocrystal competes with the radiative and non-radiative decay pathways deriving from the surface electronic states. Surface defects, for example, a dangling bond provides a non-radiative recombination center, thereby reducing the luminescence efficiency. Therefore, an effective way to passivate and remove the surface defect states is to epitaxially grow inorganic shell materials on the surface of the nanocrystals (see X. Peng et al., J. Am. Chem. Soc. Vol. 119, 7019-7029 (1997)). Type I heterojunction energy structure with shell/core structure can be achieved by selecting the shell materials so that confining the electrons, holes, and excitons to the core, resulting in decreasing the non-radiative combination. Core/shell structure can be obtained by adding organometallic precursors containing shell materials to a reaction mixture containing nucleated nanocrystals. In this case, the core act as crystalline core and grow shell on its surface rather than growing after nucleation. Reaction temperature should maintain suitably low, which facilitates to prevent independently nucleating of shell material nanocrystals when adding the shell material monomers to the core surface. The presence of surfactant in the reaction mixture serves to guide the controlled growth of the shell material and ensure solubility. When lattice mismatch is low between the two materials, uniform and epitaxially grown shells are obtained. In addition, the spherical shape serves to minimize the interfacial strain energy from the large curvature radius, thus preventing the formation of dislocations that can degrade the optical properties of the nanocrystals.

For example, the luminescent semiconductor nanocrystals may comprise a core of formula MX, where M may be cadmium, zinc, magnesium, mercury, aluminum, gallium, indium, thallium, or mixtures thereof; X may be oxygen, sulfur, selenium, tellurium, nitrogen, phosphorus, arsenic, antimony, or mixtures thereof. Examples of materials suitable for use as cores of semiconductor nanocrystals include, but not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AN, AlP, AlSb, TIN, TIP, TlAs, TlSb, PbO, PbS, PbSe, PbTe, Ge, Si, an alloy and/or mixture including any of the foregoing, including ternary and quaternary mixtures or alloys.

The semiconductor material making up the shell may be the same or different from the core composition. The shell of the semiconductor nanocrystal is an overcoating over the core surface, which may contain a Group IV element, a Group II-VI compound, a Group II-V compound, a Group III-VI compound, a Group III-V compound, a Group IV-VI compound, a Group compound, a Group II-IV-VI compound, a Group II-IV-V compound, an alloy including any of the foregoing, and/or a mixture including any of the foregoing. Examples include, but not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AN, AlP, AlSb, TIN, TIP, TlAs, TlSb, PbO, PbS, PbSe, PbTe, Ge, Si, an alloy and/or mixture including any of the foregoing.

For example, ZnS, ZnSe, or CdS shells can be grown on CdSe or CdTe semiconductor nanocrystals. For example, a method for shell growth is disclosed in U.S. Pat. No. 6,322,901. “Core/shell” semiconductor nanocrystals or quantum dots with high quantum efficiency and narrow particle size distribution can be prepared by adjusting the temperature of the reaction mixture during the shell growth, and monitoring the core absorption spectrum. The shell may comprise one or more layers. The shell comprises at least one semiconductor material which is the same as or different from the composition of the core. Preferably, the shell has a thickness from about one to about ten monolayers. A shell may also have a thickness greater than ten monolayers. In some embodiments, more than one shell can be included on a core.

In some embodiments, the surrounding “shell” material can have a band gap greater than the band gap of the core material. Preferably, the core/shell is type I heterojunction energy structure.

In some embodiments, the shell can be chosen so as to have an atomic spacing close to the “core”. In some embodiments, the shell and core materials can have the same crystal structure. Examples of “core/shell” semiconductor nanocrystals or quantum dots include, but not limited to: red (e.g., CdSe/ZnS), green (e.g., CdZnSe/CdZnS), or blue (e.g., CdS/CdZnS). The narrow particle size distribution of the semiconductor nanocrystals or quantum dots allows the possibility of light emission in narrow spectral widths. Quantum dots have been described in detail in Murray et al. (J. Am. Chem. Soc., 1993, 115, p8706), Christopher Murray's paper “Synthesis and Characterization of II-VI Quantum Dots and Their Assembly into 3-D Quantum Dot Superlattices”. Massachusetts Institute of Technology, September 1995, and U.S. Pat. No. 6,322,901. The patent document above are specially incorporated herein by reference in their entirety.

In some embodiments, two or more shells (such as CdSe/CdS/ZnS, or CdSe/ZnS/ZnS core/shell/shell structure (J. Phys. Chem. B 2004, 108, p18826)) can be introduced, and the intermediate shells between the cadmium selenide core and the zinc sulfide shell, effectively reduces the stresses inside the nanocrystals . In addition, the lattice parameters of CdS and ZnSe are intermediate between CdSe and ZnS, so that nearly defect-free nanocrystals can be obtained.

The process of controlled growth and annealing of the semiconductor nanocrystals in the coordinating solvent that follows nucleation can also result in uniform surface derivatization and uniform core structures. As the size distribution sharpens, the temperature can be raised to maintain steady growth. By adding more M donor or X donor, the growth period can be shortened. The M donor can be an inorganic compound, an organometallic compound, or a metallic element. The M donor can be a cadmium, a zinc, a magnesium, a mercury, an aluminum, a gallium, an indium, or a thallium. The X donor is a compound capable of reacting with the M donor to form a material of formula MX. The X donor can be a chalcogenide donor or a pnictide donor, such as a phosphine chalcogenide, a dioxygen, an ammonium salt, or a trisilane phosphide. Suitable X donors include, dioxygen, bis(trimethylsilyl) selenide ((TMS)₂Se), trialkyl phosphine selenides such as (tri-n-octylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl) telluride ((TMS)₂Te), bis(trimethylsilyl) sulfide ((TMS)₂S), a trialkyl phosphine sulfide such as (tri-n-octylphosphine) sulfide (TOPS), an ammonium salt such as ammonium halide (e.g., NH4C1), tris(trimethylsilyl) phosphide ((TMS)₃P), tris(trimethylsilyl) arsenide ((TMS)₃As), or tris(trimethylsilyl) antimonide ((TMS)₃Sb).

In some embodiments, the M donor and the X donor can be moieties within the same molecule. A coordinating solvent may help control the growth of the semiconductor nanocrystals. A coordinating solvent is a compound having a donor lone pair, for example, a lone electron pair available to coordinate to a surface of the growing semiconductor nanocrystal. Solvent coordination can stabilize the growing semiconductor nanocrystal. Examples of coordinating solvents include alkyl phosphines, alkyl phosphine oxides, alkyl phosphonic acids, or alkyl phosphinic acids. However, other coordinating solvents such as pyridines, furans, or amines may also be suitable for the semiconductor nanocrystal production. Additional examples of suitable coordinating solvents include pyridines, tri-n-octyl phosphines (TOP), tri-n-octyl phosphine oxides (TOPO), trishydroxylpropylphosphines (tHPP), tributylphosphines, tri(dodecyl)phosphines, dibutyl-phosphates, tributyl phosphates, trioctadecyl phosphates, trilauryl phosphates, tris(tridecyl) phosphates, triisodecyl phosphates, bis(2-ethylhexyl)phosphates, tris(tridecyl) phosphates, hexadecylamines, oleylamines, octadecylamines, bis(2-ethylhexyl)amines, octylamines, dioctylamines, trioctylamines, dodecylamines, didodecylamines, tridodecylamines, hexadecylamines, dioctadecylamines, trioctadecylamines, phenylphosphonic acids, hexylphosphonic acids, tetradecylphosphonic acids, octylphosphonic acids, octadecylphosphonic acids, propylenediphosphonic acids, phenylphosphonic acids, aminohexylphosphonic acids, dioctyl ethers, diphenyl ethers, methyl myristates, octyl octanoates, or hexyl octanoates. In some embodiments, technical grade TOPO can be used.

Size distribution during the reaction process of the growth stage can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystallites. For example, for CdSe and CdTe, by stopping growth at a particular semiconductor nanocrystal average diameter and choosing the proper composition of the semiconducting material, the emission spectrum of the semiconductor nanocrystals can be tuned continuously over the wavelength range of 300 nm to 850 nm, particularly preferably of 400 nm to 800 nm.

The particle size distribution of the semiconductor nanocrystallites can be further refined by selective precipitation with a poor solvent, such as methanol/butanol as described in U.S. Patent (i.e., U.S. Pat. No. 6,322,901B 1). For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane, chloroform/methanol, ect. The size-selected semiconductor nanocrystal population preferably has no more than 15% rms or less, more preferably 10% rms or less, and most preferably 5% rms or less.

In some embodiments, preferably, the semiconductor nanocrystals have ligands attached thereto.

In some embodiments, the ligand can be derived from a coordinating solvent during the growth process. Surface modification can be modified by repeated exposure to an excess of a competing ligand group to form an overlayer. For example, a dispersion of capped semiconductor nanocrystals can be treated with a coordinating organic compound, such as pyridine, to produce crystallites which disperse readily in pyridine, methanol, and aromatics, but no longer disperse in aliphatic solvents. Such a surface exchange process can be carried out with any compound capable of coordinating to or bonding with the outer surface of the semiconductor nanocrystal, including, phosphines, thiols, amines, or phosphates. The semiconductor nanocrystal can also be exposed to short chain polymers that exhibit an affinity with the semiconductor nanocrystal at one end and a group at the other end that has an affinity with the liquid medium in which the semiconductor nanocrystals are dispersed. Such affinity improves the stability of the suspension and discourages flocculation of the semiconductor nanocrystal. In addition, in some embodiments, the semiconductor nanocrystals may be prepared using a non-coordinating solvent.

More specifically, the coordinating ligand have the formula:

(Y—)ₖ₋ₙ—(X)—(—L)ₙ

Where k is 2, or 3, or 4, or 5; n is 1, or 2, or 3, or 4, or 5 such that k-n is not less than zero; X is selected from O, O—S, O—Se, O—N, O—P, O—As, S, S═O, SO₂, Se, Se═O, N, N═O, P, P═O, O═C═As, or As═O; each of Y and L is independently from each other and may be H, OH, aryl, heteroaryl, a C₂-C₁₈ linear/branched hydrocarbon chain optionally containing at least one double bond, at least one triple bond, or at least one double bond and one triple bond. The hydrocarbon chain can be optionally substituted with one or more C₁-C₄ alkyls, C₂-C₄ alkenyls, C₂-C₄ alkynyls, C₁-C₄ alkoxys, hydroxyls, halos, aminos, nitros, cyanos, C₃-C₅ cycloalkyls, 3-5 membered heterocycloalkyls, aryls, heteroaryls, C₁-C₄ alkylcarbonyloxys, C₁-C₄ alkyloxycarbonyls, C₁-C₄ alkylcarbonyls, or formyls. The hydrocarbon chain can also be optionally interrupted by —O—, —S—, —N(Ra)—, —N(Ra)—C(O)—O, —O—C(O)—N(Ra)—, —N(Ra)—C(O)—N(Rb)—, —O—C(O)—O, —P(Ra)—, or —P(O)(Ra)—. Each of Ra and Rb is independently and may be hydrogen, alkyl, alkenyl, alkynyl, alkoxy, hydroxylalkyl, hydroxyl, or haloalkyl. An aryl group is a substituted/unsubstituted cycloaromatic group. Examples include benzene, naphthalene, toluene, anthracene, nitrobenzene, or halogenated phenyl. A heteroaryl is an aryl with one or more heteroatoms, such as furan ring, pyridine, pyrrole, or phenanthrenyl.

A suitable coordinating ligand can be purchased commercially or prepared by ordinary synthetic organic techniques, for example, as described in J. March, Advanced Organic Chemistry, which is incorporated by reference in its entirety. Other ligands are disclosed in U.S. Pat. No. 7,160,613, which is hereby incorporated by reference in its entirety.

The emission spectrum of the semiconductor nanocrystals or the quantum dots can be a narrow Gaussian that can be tuned through the complete wavelength range of the ultraviolet, visible, or infra-red regions of the spectrum by varying the size of the nanocrystallite, the composition of the nanocrystallite, or both. For example, a quantum dot comprising CdSe can be tuned in the visible region; a quantum dot or a semiconductor nanocrystal comprising InAs can be tuned in the infra-red region. The narrow particle size distribution of a luminescent semiconductor nanocrystal or a quantum can result in a narrow emission spectrum. The crystallites population can be monodisperse preferably exhibits less than a 15% rms deviation in diameter, more preferably less than 10% rms, and most preferably less than 5% rms. For semiconductor nanocrystallites or quantum dots that emit visible light, the emission spectrum can have a FWHM of no greater than 75 nm, preferably no greater than 60 nm, more preferably no greater than 40 nm, and most preferably no greater than 30 nm. For semiconductor nanoparticles or quantum dots that emit infrared light, the emission spectrum can have a FWHM of not greater than 150 nm, or not greater than 100 nm. The width of the emission spectrum decreases as the width of the particle size distribution of the quantum dots decreases.

Semiconductor nanocrystals can have emission quantum efficiencies such as greater than 10%, 20%, 30%, 40%, 50%, 60%. In some embodiments, the semiconductor nanocrystals or the quantum dots have emission quantum efficiencies of greater than 70%, preferably greater than 80%, and most preferably greater than 90%.

The narrow FWHM of the quantum dots can result in saturated color emission. The broadly tunable, saturated color emission over the entire visible spectrum of a single material system is unmatched by any class of organic chromophores (see, e.g., Dabbousi et al., J. Phys. Chem. 1997, 101, p9463). Quantum dots will emit light spanning a narrow range of wavelengths. A pattern including more than one quantum dot can emit light in more than one narrow range of wavelengths. The color of emitted light perceived by a viewer can be controlled by selecting appropriate combinations of quantum dot sizes and materials. Transmission electron microscopy (TEM) can provide information about the size, shape, and distribution of the crystallite population. Powder X-ray diffraction (XRD) spectrum can provide the most complete information regarding the types and qualities of the crystallites. Estimates of the crystallite sizes are also possible since particle diameter is inversely related, via the X-ray coherence length, to the peak width. For example, the diameter of the quantum dot can be measured directly by transmission electron microscopy or estimated from X-ray diffraction data using, for example, the Scherrer equation. It also can be estimated from the UV/Vis absorption spectrum.

Other materials, techniques, methods, applications, and information which may be useful for the present disclosure are described in the following patent documents, WO2007117698, WO2007120877, WO2008108798, WO2008105792, WO2008111947, WO2007092606, WO2007117672, WO2008033388, WO2008085210, WO200813366, WO2008063652, WO2008063653, WO2007143197, WO2008070028, U.S. Pat. Nos. 6,207,229, 6,251,303, 6,319,426, 6,426,513, 6,576,291, 6,607,829, 6,861,155, 6,921,496, 7,060,243, 7,125,605, 7,138,098, 7,150,910, 7,470,379, 7,566,476, WO2006134599A1. The patent documents listed above are specially incorporated herein by reference in their entirety.

In some embodiments, the luminescent semiconductor nanocrystals are nanorods. The properties of the nanorods differ from those spherical nanocrystallites. For example, the luminescence of the nanorods is polarized along the long rod axis, while the luminescence of spherical crystallite is unpolarized (see Woggon et al., Nano Lett., 2003, 3, p509); the nanorods have excellent optical gain properties, making them potentially usable as a laser gain material (see Banin et al., Adv. Mater. 2002, 14, p317); furthermore, the luminescence of the nanorods can be reversibly switched on and off under the control of an external electric field (see Banin et al., Nano Lett. 2005, 5, p1581). These properties of the nanorods may be preferentially incorporated into the devices of the present disclosure in certain circumstances. Examples of prepared semiconductor nanorods are WO03097904A1, US2008188063A1, US2009053522A1, KR20050121443A. The patent documents listed above are specially incorporated herein by reference in their entirety.

In some embodiments, the emission wavelength range of the semiconductor emitter is from UV to near infrared, preferably from 350 nm to 850 nm, more preferably from 380 nm to 800 nm, and most preferably from 380 nm to 680 nm.

In some embodiments, the inorganic nanoemitter E is a heterostructure comprising two different semiconductors, and the heterostructure is a core/shell structure with at least one shell.

In some embodiments, the inorganic nanoemitter E is a luminescent metal nanocluster.

In general, the metal nanocluster comprises a core consisting of metal atoms and a cap surrounding the metal core. The role of the cap is to protect the core and stabilize it while increasing the solubility of the nanocluster in various solvents. The cap generally comprises organic materials. In some embodiments, the cap may comprise thiols such as alkyl mercaptans, octadecanethiols, polymers, dendrimer, DNA oligonucleotides, glutathione, peptides, proteins, or derivatives thereof. More preferably, the cap may comprise a dendrimer selecting from various different generations of OH-terminated dendrimer poly(amidoamine) PAMAM. This dendrimer is commercially available, e.g. from Aldrich Inc.

In the electroluminescent device as described herein, the core of the metal nanocluster <4 nm. In some embodiments, the core of the metal nanocluster <3 nm, more preferably <2 nm, and most preferably <1 nm.

In some embodiments, the core size of the metal nanocluster may be measured by its quantity of comprised metal atoms. In general, the quantity of comprised metal atoms ≤200, preferably ≤150, more preferably ≤100, and most preferably ≤80. In some embodiments, the quantity of comprised metal atoms in the core of the metal nanocluster is the so-called magic number, which is 2, 8, 20, 28, 50, 82, 126, etc. When the quantity of the comprised metal atoms in the core of the metal nanocluster are these magic numbers, its stability is high.

The core of the metal nanocluster may comprise any metal element. In some embodiments, the metal element of the metal nanocluster core is selected from Au, Ag, Pt, Pd, Cu, alloys thereof, or any combination thereof. In some embodiments, the metal element of the metal nanocluster core is selected from Au, Ag, alloys thereof, or any combination thereof. In some embodiments, the metal element of the metal nanocluster core is Au, or Ag.

The syntheses, characterization methods, and properties of the various metal nanoclusters are described in detail in numerous reviews, such as Li Shang et al., Nano Today (2011) 6, 401-418; Jie Zhang et al., Annu. Rev. Phys. Chem. (2007) 58, 409-31, Marie-Christine Daniel & Didier Astruc, Chem. Rev. 2004, 104, 293-346; Jun Yang et al., Chem. Soc. Rev. 2011, 40, 1672-1696. The patent documents listed above are specially incorporated herein by reference in their entirety.

In some embodiments, the core of the metal nanocluster is heterojunction which is core/shell structure with at least one shell containing two different materials. Examples and syntheses of the metal nanoclusters with a core/shell structure may be found in Christopher J. Serpell et al., Nat. Chem. 3 (2011), 478, S. Mohan et al., Appl. Phys. Lett. 91 (2007), 253107, Tetsu Yonezawa, Nanostructure Sci. Technol. (2006) 251.

In the mixture as described herein, the organic compound H has relatively high extinction coefficient. The extinction coefficient is also known as the molar extinction coefficient, which refers to the absorption coefficient at a concentration of 1 mol/L, and is represented by the symbol ϵ, in unit of Lmol⁻¹ cm⁻¹. The extinction coefficient (E) preferably ≥1*10³; more preferably ≥1*10⁴; particularly preferably ≥5*10⁴; and most preferably >1*10⁵. Preferably, the extinction coefficient refers to the extinction coefficient at the wavelength corresponding to the absorption peak.

In some embodiments, the absorption spectrum of the organic compound H is between 380 nm and 500 nm.

In some embodiments, the emission spectrum of the organic compound H is between 440 nm and 500 nm.

In some embodiments, the wavelength of the emission peak of the organic compound H<500 nm.

In some embodiments, the emission spectrum of the organic compound H is between 500 nm and 580 nm.

As used herein, the energy level structure of the organic material, triplet energy level (Ti), singlet energy level (Si), highest occupied molecular orbital (HOMO), lowest unoccupied molecular orbital (LUMO), and oscillator strength f play key roles on its optoelectronic performance and stability. The determination of these parameters is introduced as follows.

HOMO and LUMO energy levels can be measured by optoelectronic effect, for example by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT) are becoming effective method for calculating the molecular orbital energy levels.

The triplet energy level T1 of an organic material can be measured by low-temperature time-resolved spectroscopy, or calculated by quantum simulation (for example, by Time-dependent DFT), for instance with the commercial software Gaussian 03W (Gaussian Inc.), the specific simulation method as described below.

The singlet energy level S1 of the organic material can be determined by the absorption spectrum or the emission spectrum, and can also be calculated by quantum simulation (such as Time-dependent DFT); the oscillator strength f can also be calculated by quantum simulation (such as Time-dependent DFT)

It should be noted that the absolute values of HOMO, LUMO, T1 and S1 may vary depending on the measurement method or calculation method used. Even for the same method, different ways of evaluation, for example, using either the onset or peak value of a CV curve as reference, may result in different (HOMO/LUMO) values. Therefore, reasonable and meaningful comparison should be carried out by using the same measurement and evaluation methods. In the embodiments of the present disclosure, the values of HOMO, LUMO, T1 and S1 are based on the Time-dependent DFT simulation, which however should not exclude the applications of other measurement or calculation methods.

Preferably, the organic compound H as described herein has relatively large S1-T1, where the S1-T1 generally ≥0.70 eV, preferably ≥0.80 eV, more preferably ≥0.90 eV, further preferably ≥1.00 eV, and most preferably ≥1.10 eV.

In some embodiments, the organic compound H has relatively large AHOMO and/or ALUMO, generally ≥0.50 eV, preferably ≥0.60 eV, more preferably ≥0.70 eV, further preferably >0.80 eV, and most preferably ≥0.90 eV; where ΔHOMO=HOMO−(HOMO−1), ΔLUMO=(LUMO+1)−LUMO.

For the purposes of the present disclosure, (HOMO-1) is defined as the energy level of the second highest occupied molecular orbital, (HOMO-2) is defined as the energy level of the third highest occupied molecular orbital, and so on. (LUMO+1) is defined as the energy level of the second lowest unoccupied molecular orbital, (LUMO+2) is defined as the energy level of the third lowest occupied molecular orbital, and so on; these energy levels can be determined by the following simulation method.

In some embodiments, the organic compound H has relatively large oscillator strength f(Sn) (n≥1); f(S1) generally ≥0.20 eV, preferably ≥0.30 eV, more preferably ≥0.40 eV, further preferably ≥0.50 eV, and most preferably ≥0.60 eV.

In some embodiments, the organic compound H has relatively low HOMO, generally ≤−5.0 eV, preferably ≤−5.1 eV, more preferably ≤−5.2 eV, further preferably ≤−5.3 eV, and most preferably ≤−5.4 eV.

In some embodiments, the organic compound H has a relatively high LUMO, generally ≥−3.0 eV, preferably ≥−2.9 eV, more preferably ≥−2.8 eV, further preferably ≥−2.7 eV, and most preferably ≥−2.6 eV.

The suitable organic compounds H may be selected from organic small molecules, polymers, or metal complexes.

In some embodiments, the organic compound H may be selected from cyclic aromatic hydrocarbon compound, such as benzene, biphenyl, triphenylbenzene, benzophenanthrene, triphenylene, anthracene, phenalene, phenanthrene, fluorene, pyrene, chrysene, perylene, azulene. The organic compound used as the singlet host material may be also selected from aromatic heterocyclic compound, such as dibenzothiophene, dibenzofuran, dibenzothiophene, furan, thiophene, benzofuran, benzothiophene, benzoselenophene, carbazole, indocarbazole, pyridindole, pyrroledipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, Benzoisoxazole benzothiazole, quinoline, isoquinoline, cinnoline, quinazoline, quinoxaline, naphthalene, phthalein pteridine, xanthene, acridine, phenazine, phenothiazine, phenoxazine, benzofuranopyridine, furandipyridine, benzothienopyridine, thiophenedipyridine, benzoselenophenopyridine, or selenophenodipyridine. The organic compound used as the singlet host material may be selected from groups containing 2 to 10 ring structures, which may be the same or different types of cyclic aryl or heterocyclic aryl, and are linked to each other directly or by at least one of the following groups, such as oxygen atom, nitrogen atom, sulfur atom, silicon atom, phosphorus atom, boron atom, chain structure unit, or aliphatic ring group.

In some embodiments, the organic compound H may be selected from the compound comprising at least one of the following groups:

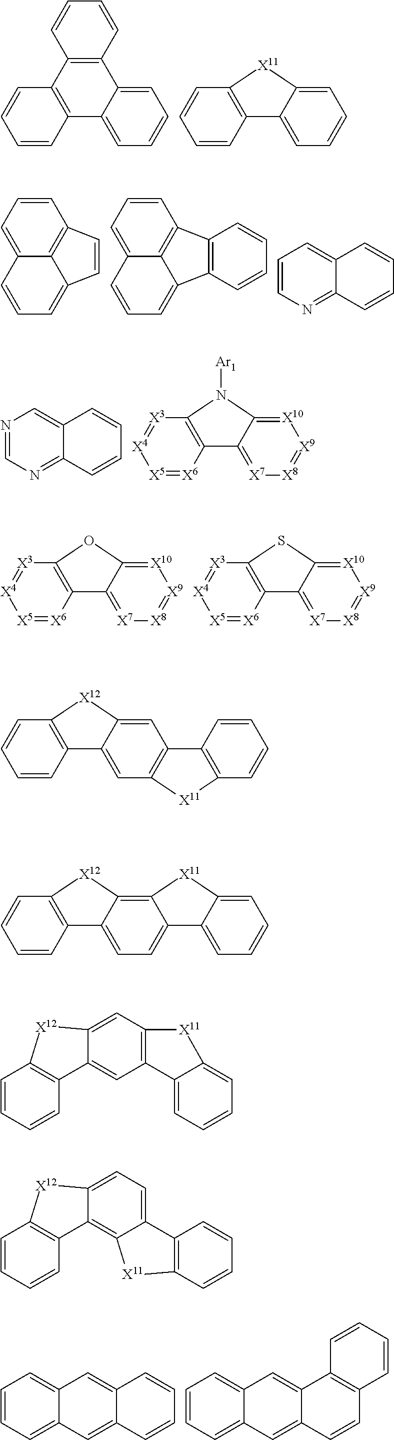

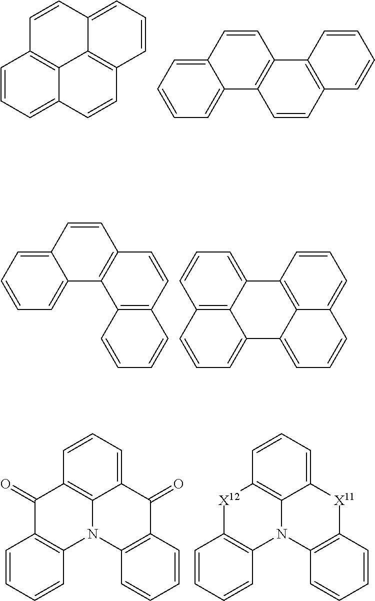

Where Ar₁ is aryl or heteroaryl; each of X³ to X¹⁰ is CR¹ or N; X¹¹ and X¹² are independently selected from CR¹R², NR¹, or O.

R¹ and R² are independently selected from the group consisting of —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂o branched/cyclic silyl group, a C₁-C₂₀ substituted ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, and a disubstituted unit in any position of the above substituents or a combination thereof, where one or more R¹-R² may form a monocyclic or polycyclic aliphatic or aromatic ring system with each other and/or with the rings bonded thereto.

In some embodiments, the organic compound H has a long conjugated π-electron system. Hitherto, there have been many examples of styryl amines and derivatives thereof as disclosed in JP2913 116B and WO2001021729A1, and indenofluorenes and derivatives thereof as disclosed in WO2008006449 and WO2007140847.

In some embodiments, the organic compound H can be selected from the group consisting of monostyrylamines, distyrylamines, tristyrylamines, tetrastyrylamines, styrenphosphines, styrenethers, and arylamines.

A monostyrylamine refers to a compound which comprises one unsubstituted or substituted styryl group and at least one amine, most preferably an aryl amine. Distyrylamine refers to a compound comprising two unsubstituted or substituted styryl groups and at least one amine, most preferably an aryl amine. Ternarystyrylamine refers to a compound which comprises three unsubstituted or substituted styryl groups and at least one amine, most preferably an aryl amine. Quaternarystyrylamine refers to a compound comprising four unsubstituted or substituted styryl groups and at least one amine, most preferably an aryl amine. Preferred styrene is stilbene, which may be further substituted. The corresponding phosphines and ethers are defined similarly as amines. Aryl amine or aromatic amine refers to a compound comprising three unsubstituted or substituted cyclic or heterocyclic aryl systems directly attached to nitrogen. At least one of these cyclic or heterocyclic aryl systems is preferably selected from fused ring systems and most preferably has at least 14 aryl ring atoms. Among the preferred examples are aryl anthramine, aryl anthradiamine, aryl pyrene amines, aryl pyrene diamines, aryl chrysene amines and aryl chrysene diamine. Aryl anthramine refers to a compound in which one diarylamino group is directly attached to anthracene, most preferably at position 9. Aryl anthradiamine refers to a compound in which two diarylamino groups are directly attached to anthracene, most preferably at positions 9,10. Aryl pyrene amines, aryl pyrene diamines, aryl chrysene amines and aryl chrysene diamine are similarly defined, where the diarylarylamino group is most preferably attached to position 1 or 1,6 of pyrene.

Examples of organic compounds H based on vinylamines and arylamines may be found in the following patent documents: WO2006000388, WO2006058737, WO2006000389, WO2007065549, WO2007115610, US7250532B2, DE102005058557A1, CN1583691A, JP08053397A, U.S. Pat. NO. 6,251,531B1, US2006210830A, EP1957606A1, and US20080113101A1. The patent documents listed above are specially incorporated herein by reference in their entirety.

Examples of organic compounds H based on stilbene and its derivatives may be found in U.S. Pat. No. 5,121,029.

Further preferred organic compound H can be selected from the group consisting of indenofluorene-amine and indenofluorene-diamine, as disclosed in WO2006122630, benzoindenofluorene-amine and benzoindenofluorene-diamine, as disclosed in WO2008006449, dibenzoindenofluorene-amine and dibenzoindenofluorene-diamine, as disclosed in WO2007140847.

Other materials that can be used as organic compound H include polycyclic aromatic hydrocarbon compounds, in particular selected from the derivatives of the following compounds: anthracene such as 9,10-di(2-naphthyl)anthracene, naphthalene, tetraphenyl, phenanthrene, perylene such as 2,5,8,11-tetra-t-butylatedylene, indenoperylene, phenylene (benzo fused ring such as 4,4′ -(bis (9-ethyl-3-carbazovinylene)-1,1′-biphenyl)), periflanthene, decacyclene, coronene, fluorene, spirobifluorene, arylpyren (e.g., US20060222886), arylenevinylene (e.g. U.S. Pat. Nos. 5,121,029, 5,130,603), cyclopentadiene such as tetraphenylcyclopentadiene, rubrene, coumarine, rhodamine, quinacridone, pyrane such as 4 (dicyanoethylene)-6-(4-dimethylaminostyryl-2-methyl)-4H-pyrane (DCM), thiapyran, bis (azinyl) imine-boron compounds (e.g. US20070092753A1), bis (azinyl) methene compounds, carbostyryl compounds, oxazone, benzoxazole, benzothiazole, benzimidazole, or diketopyrrolopyrrole. Some singlet emitter materials may be found in the following patent documents: US20070252517A1, U.S. Pat. Nos. 4,769,292, 6,020,078. The patent documents listed above are specially incorporated herein by reference in their entirety.

The publications of organic functional material presented above are incorporated herein by reference for the purpose of disclosure.

In some embodiments, the organic compound H comprises at least one alcohol-soluble or water-soluble group; preferably comprises at least two alcohol-soluble or water-soluble groups; and most preferably comprises at least three alcohol-soluble or water-soluble groups.

In some embodiments, the organic compound H comprises at least one cross-linkable group; preferably comprises at least two cross-linkable groups; and most preferably comprises at least three cross-linkable groups.

Examples of some suitable organic compounds H are listed below (but not limited to), which may be further substituted arbitrarily:

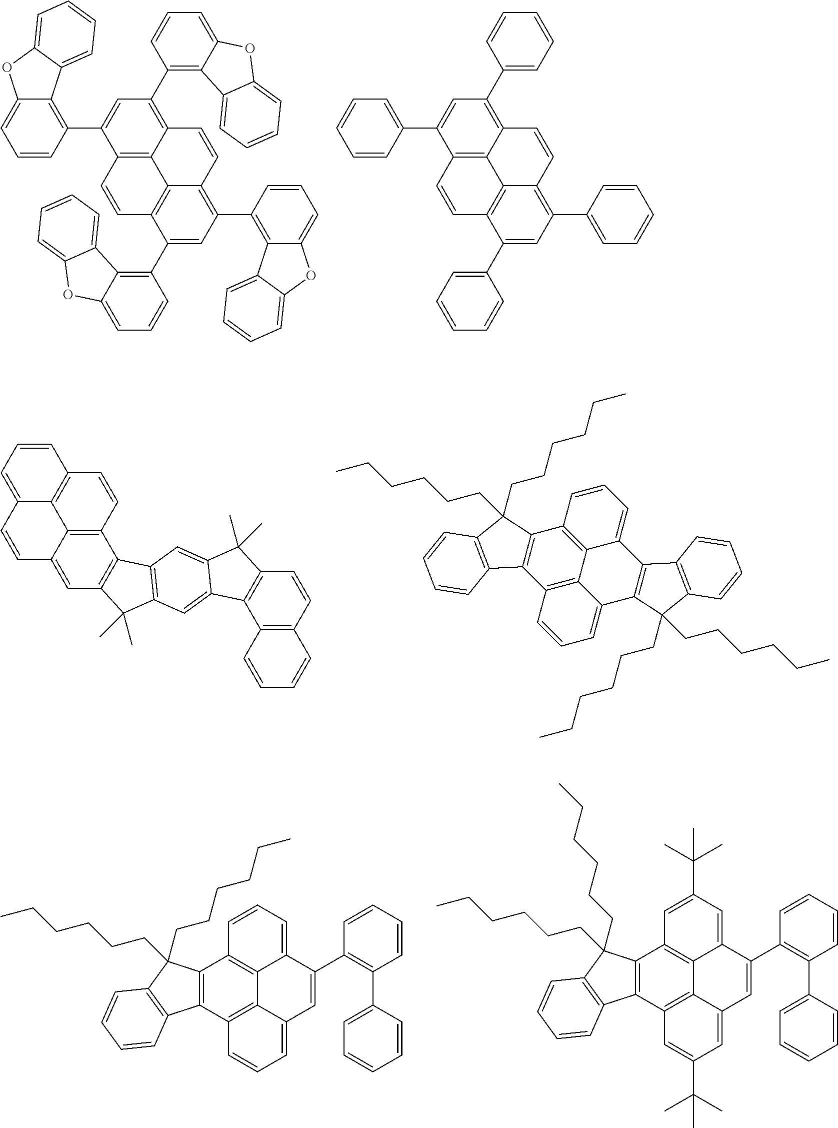

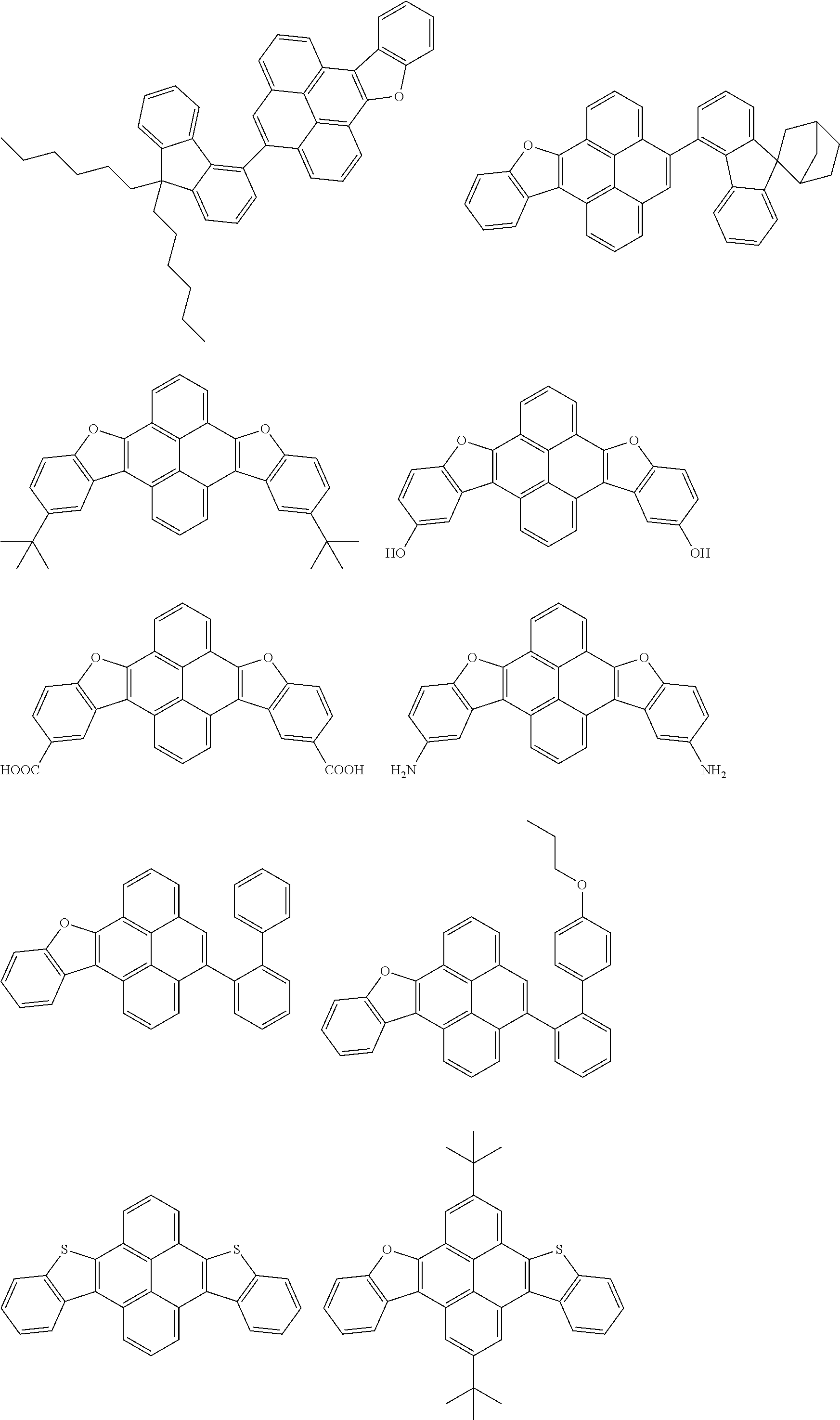

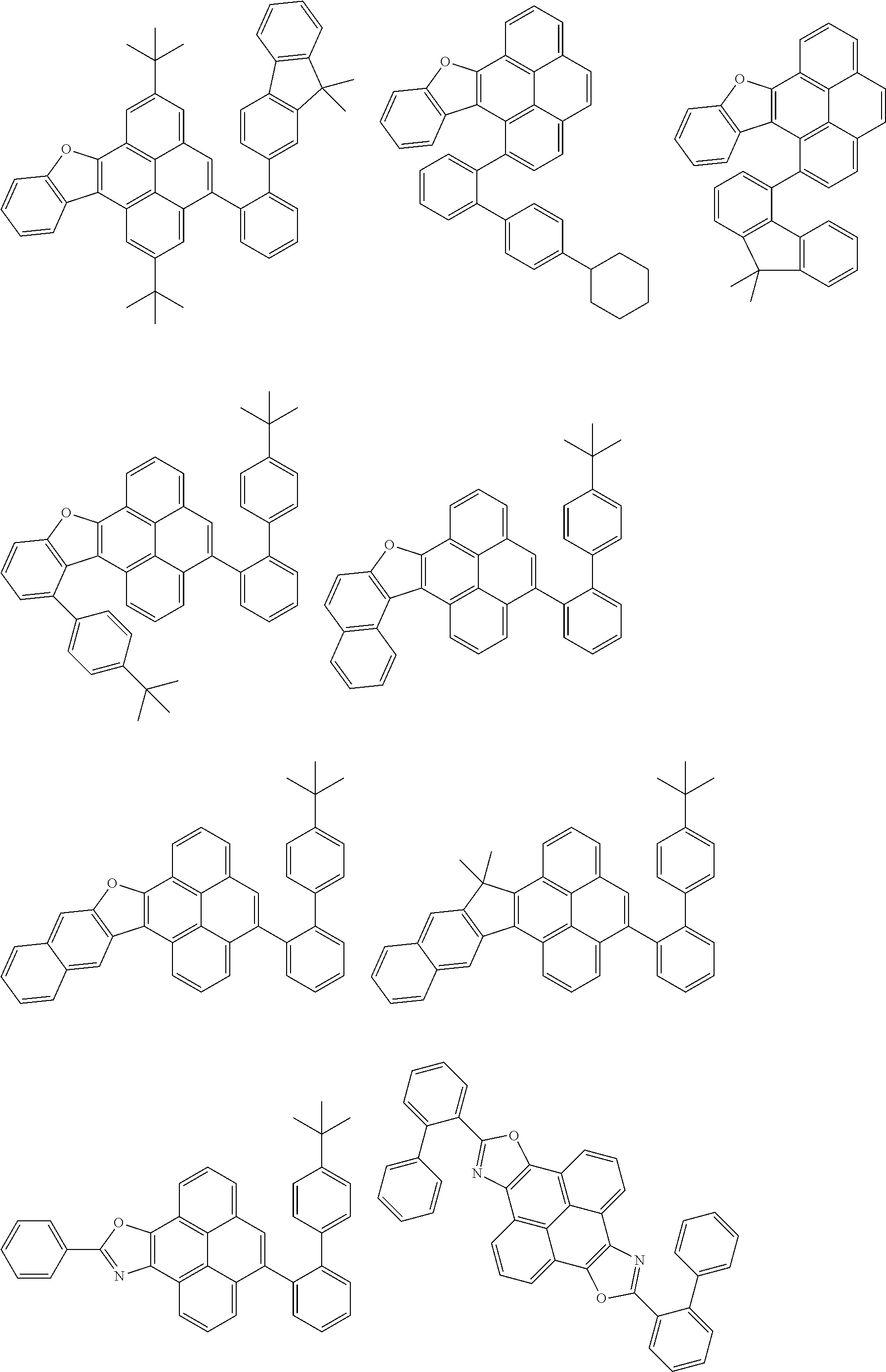

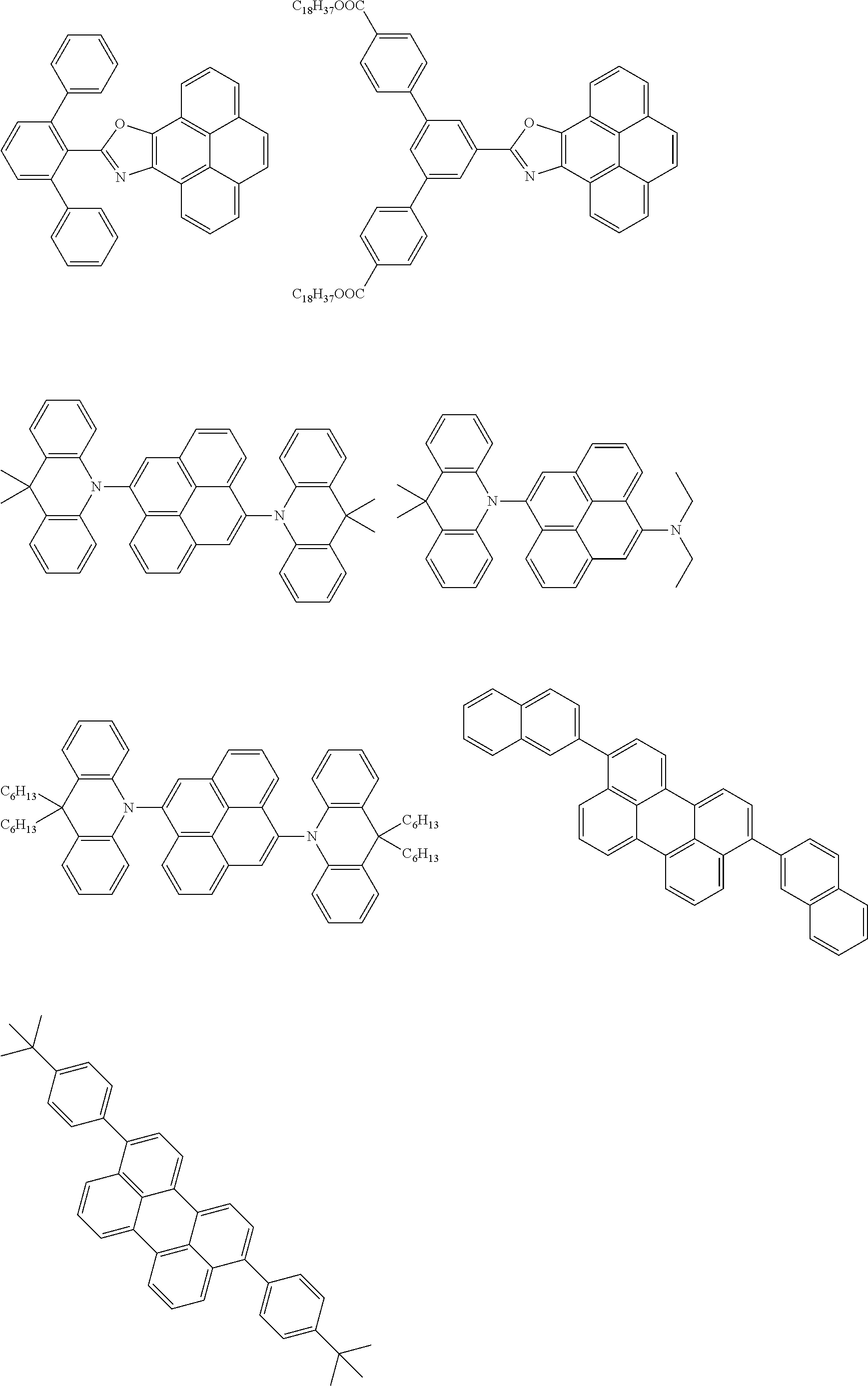

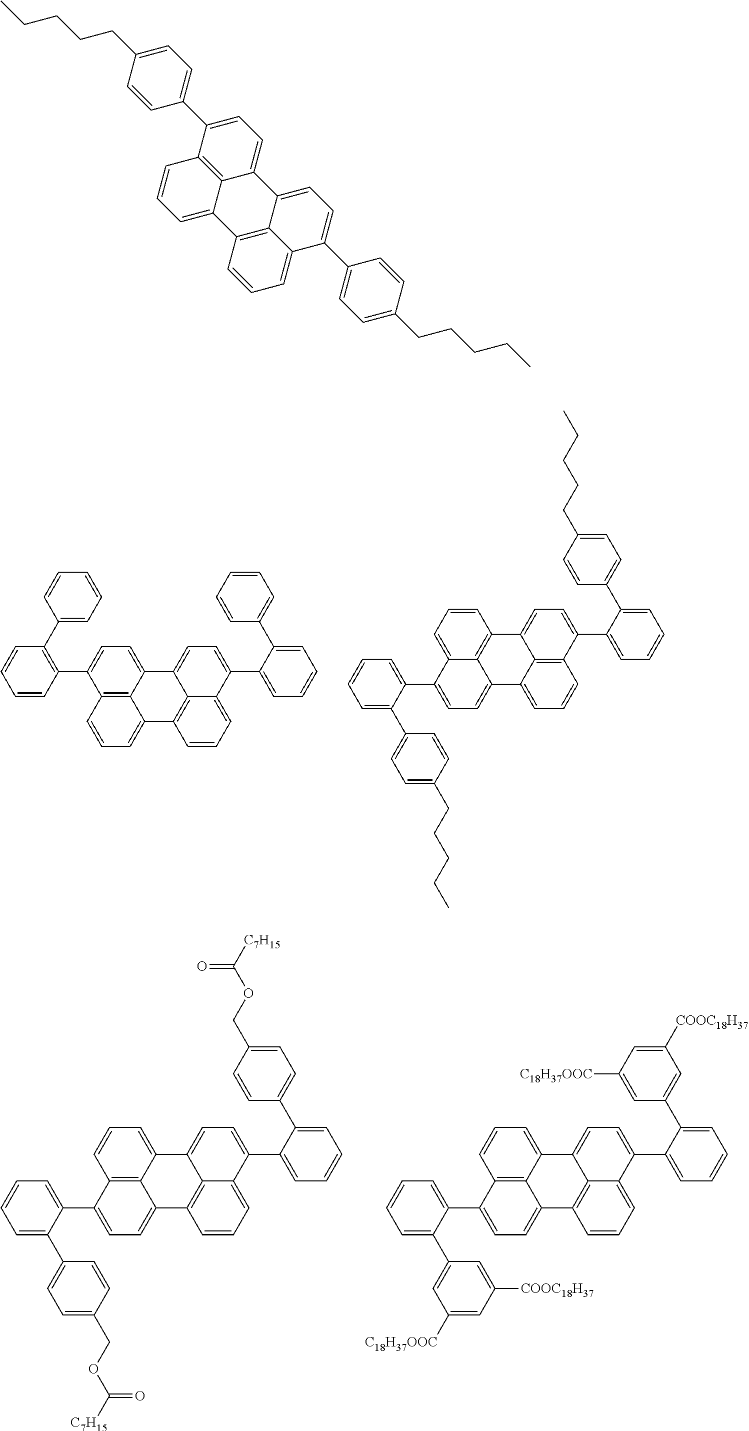

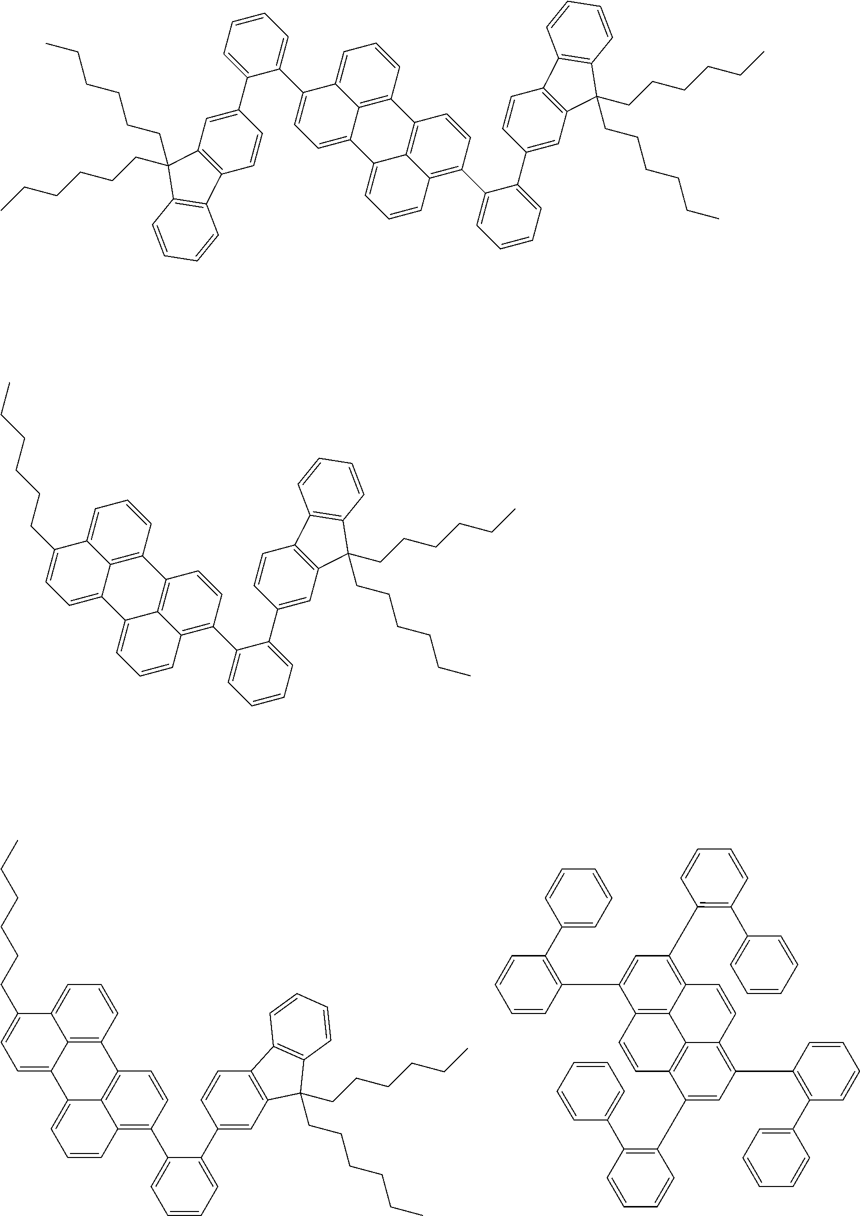

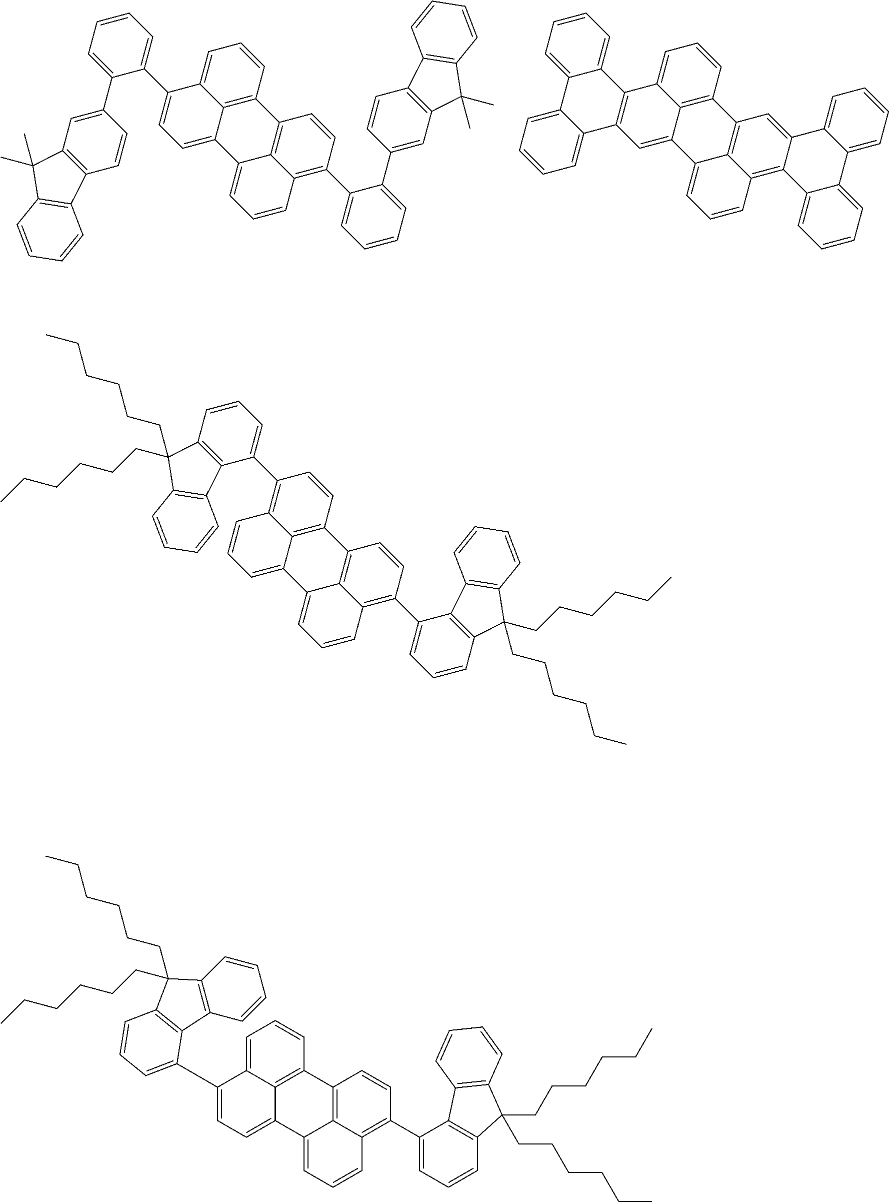

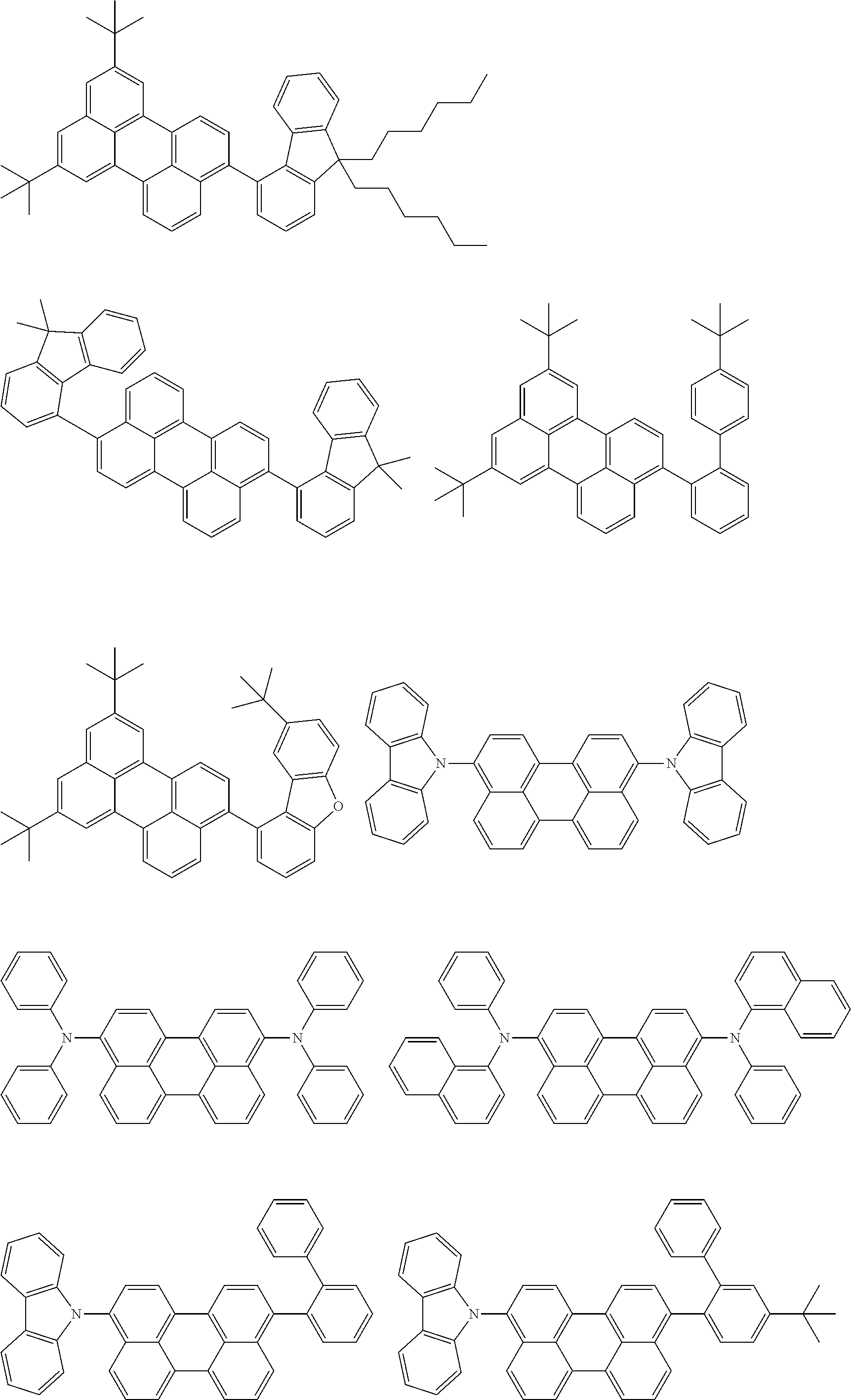

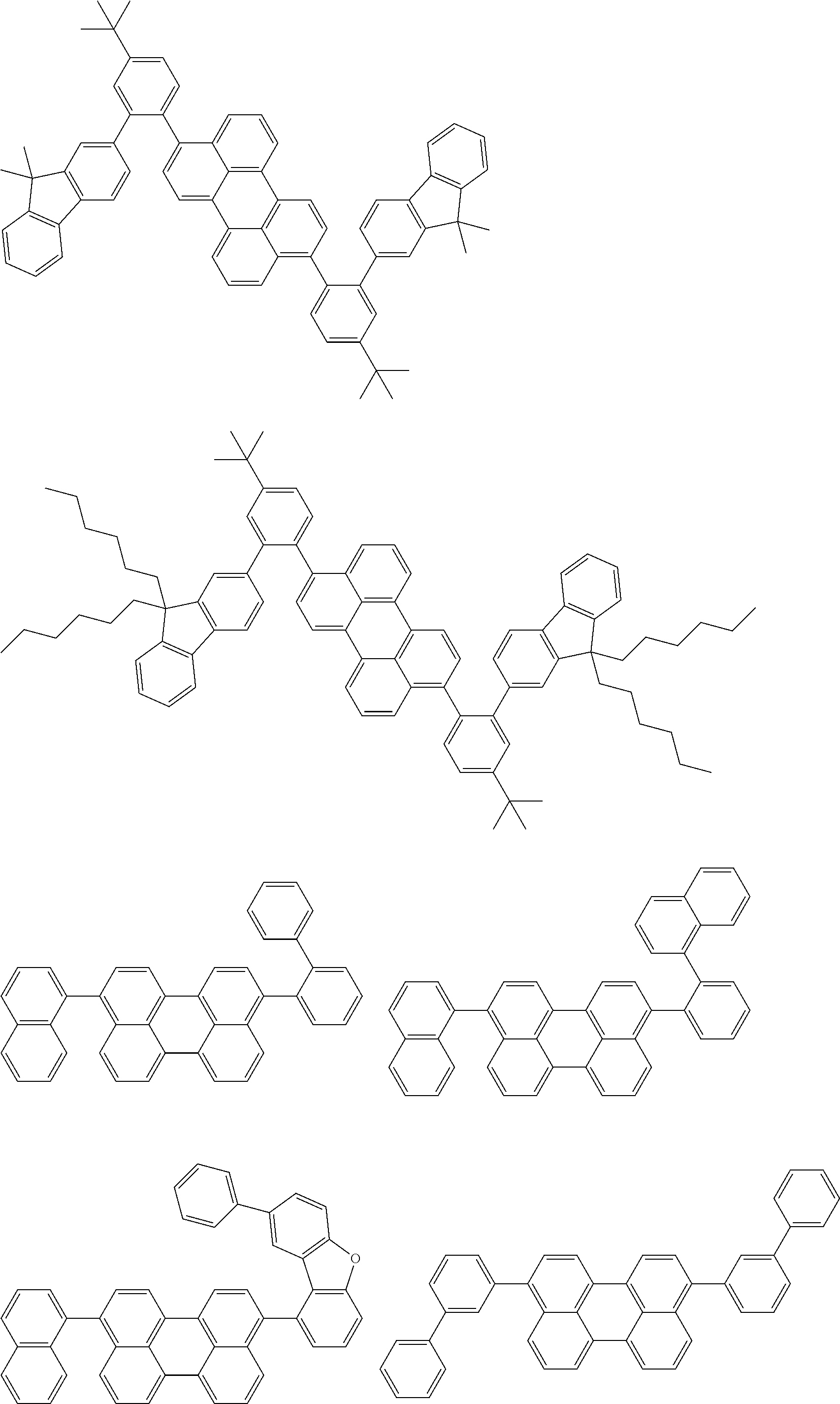

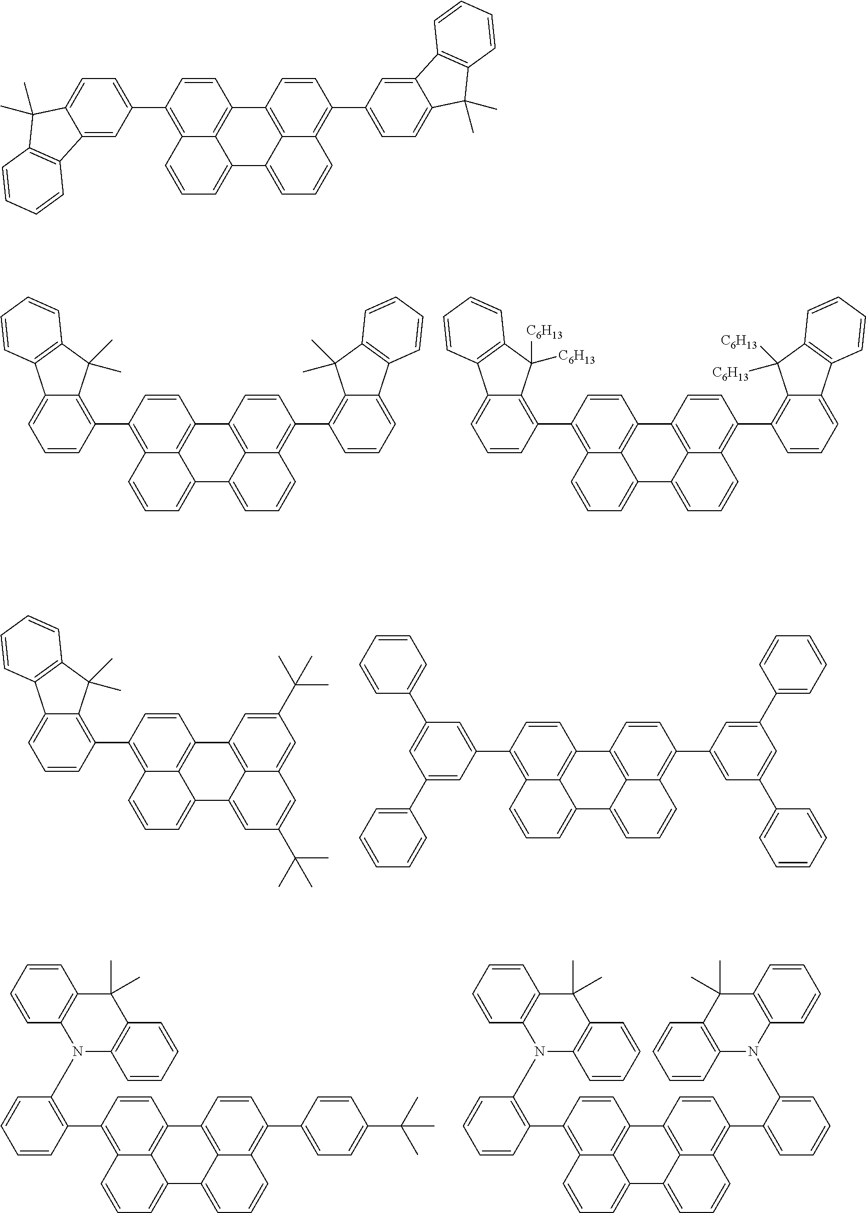

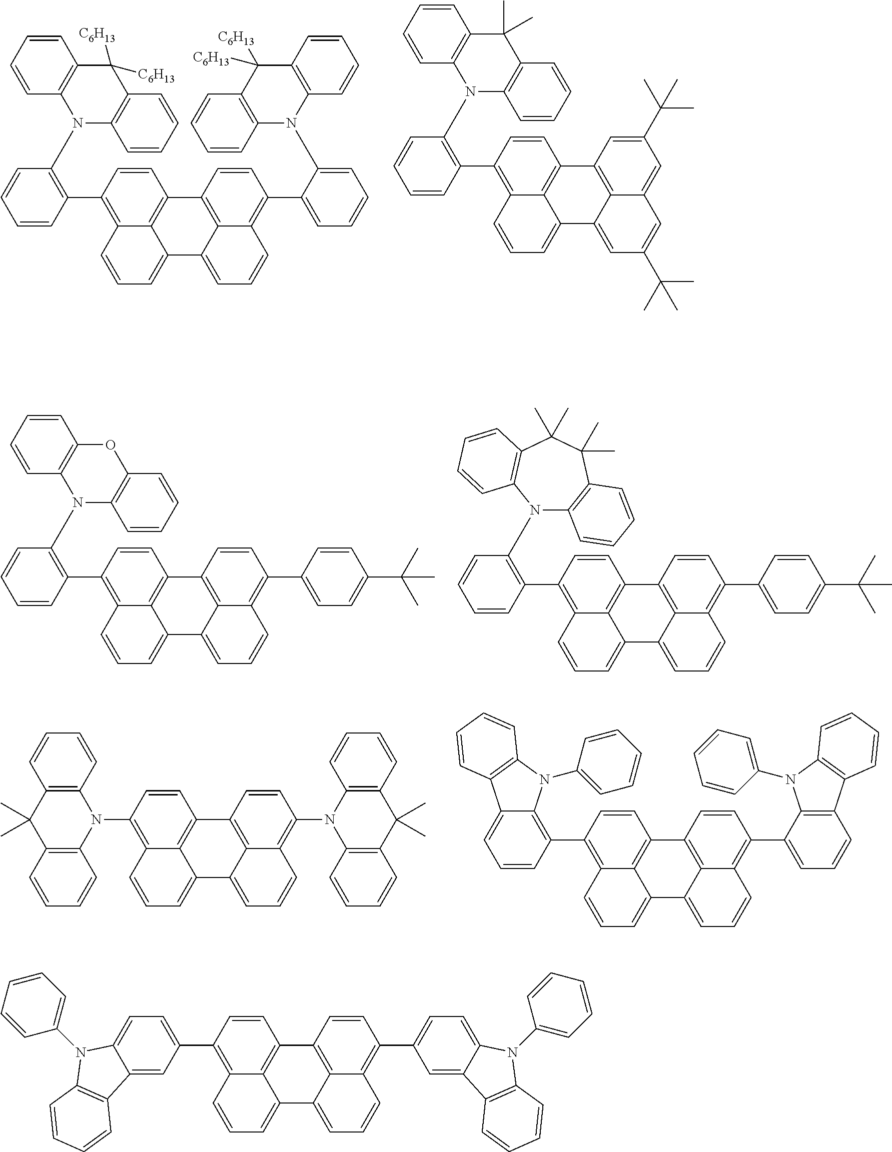

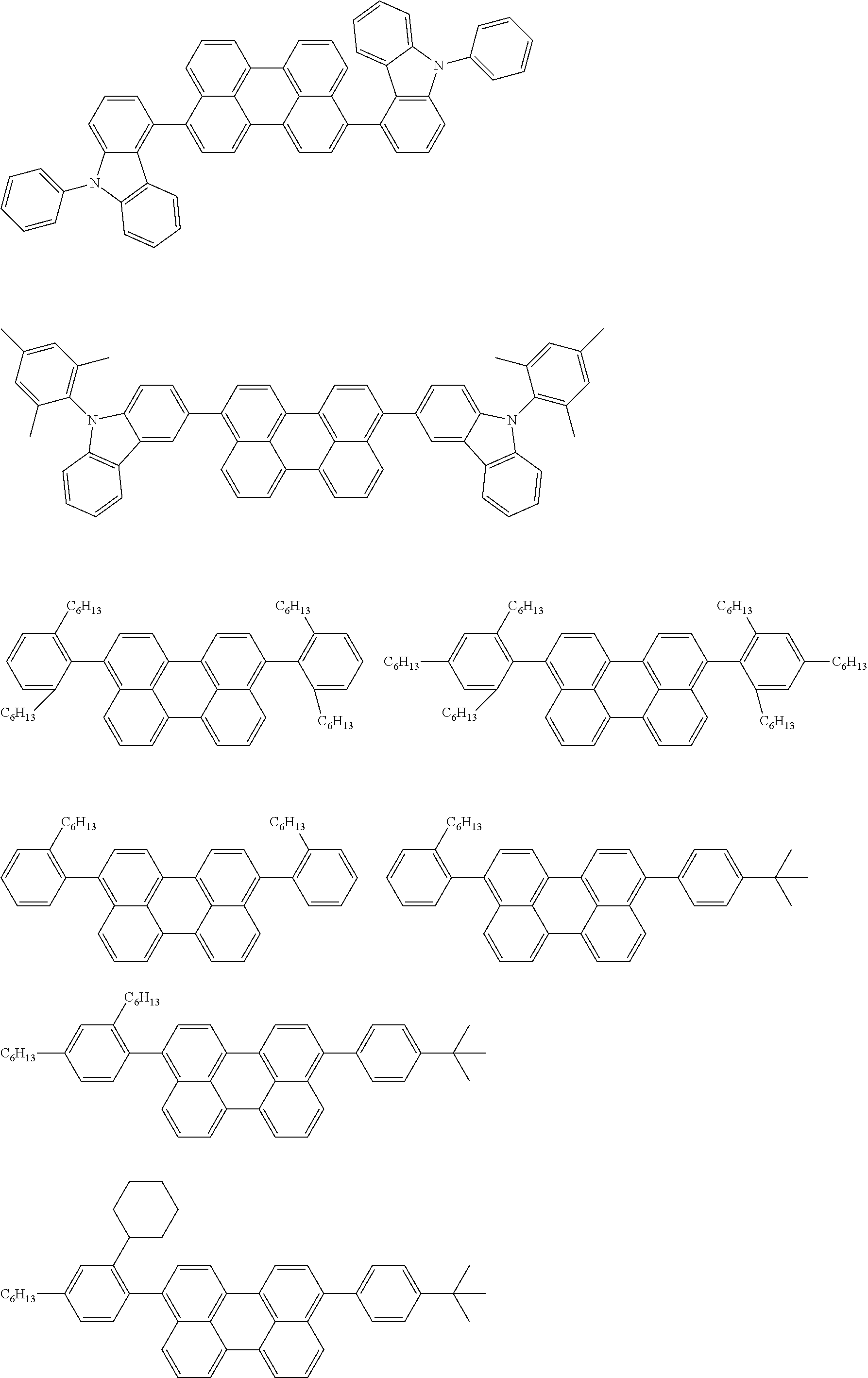

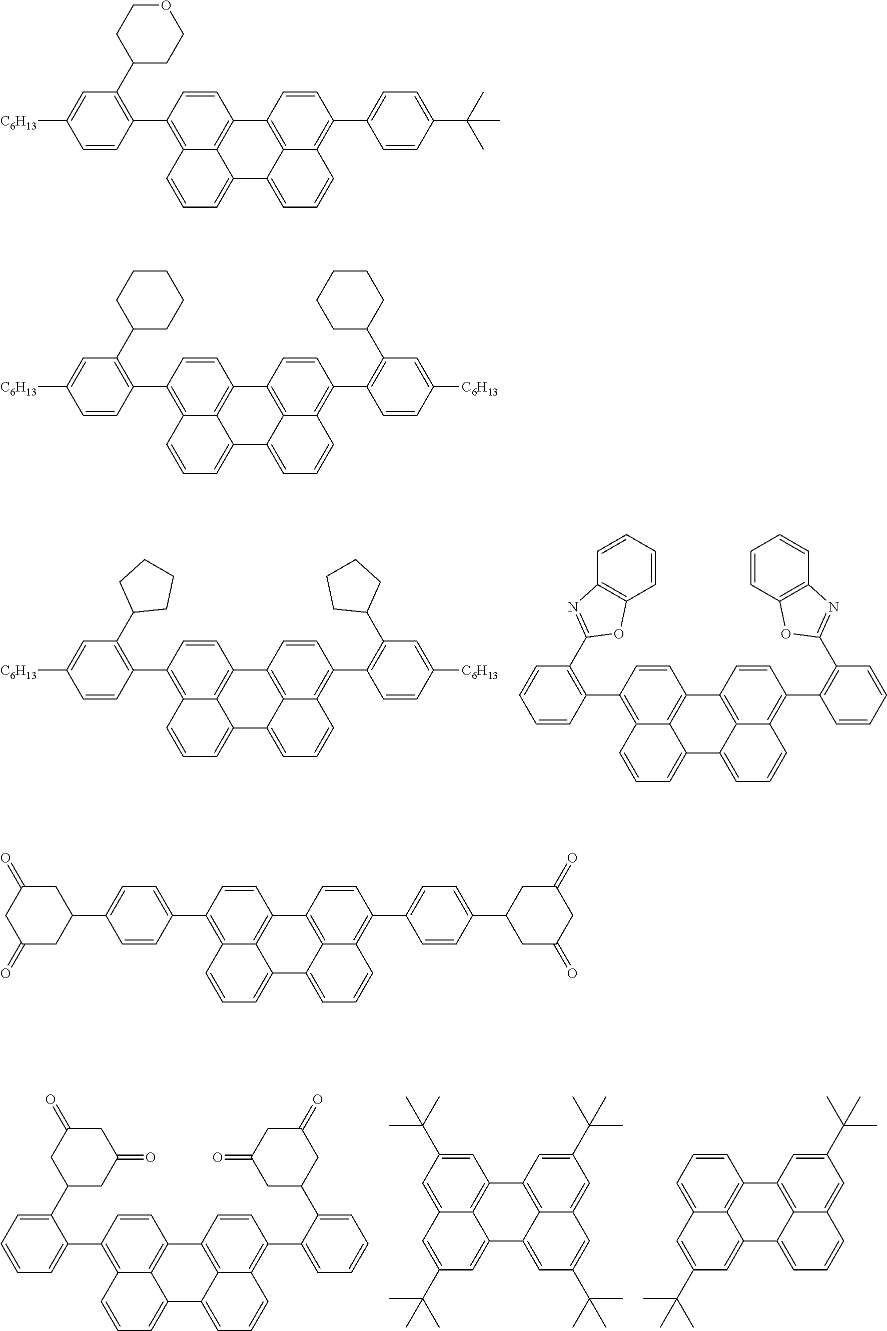

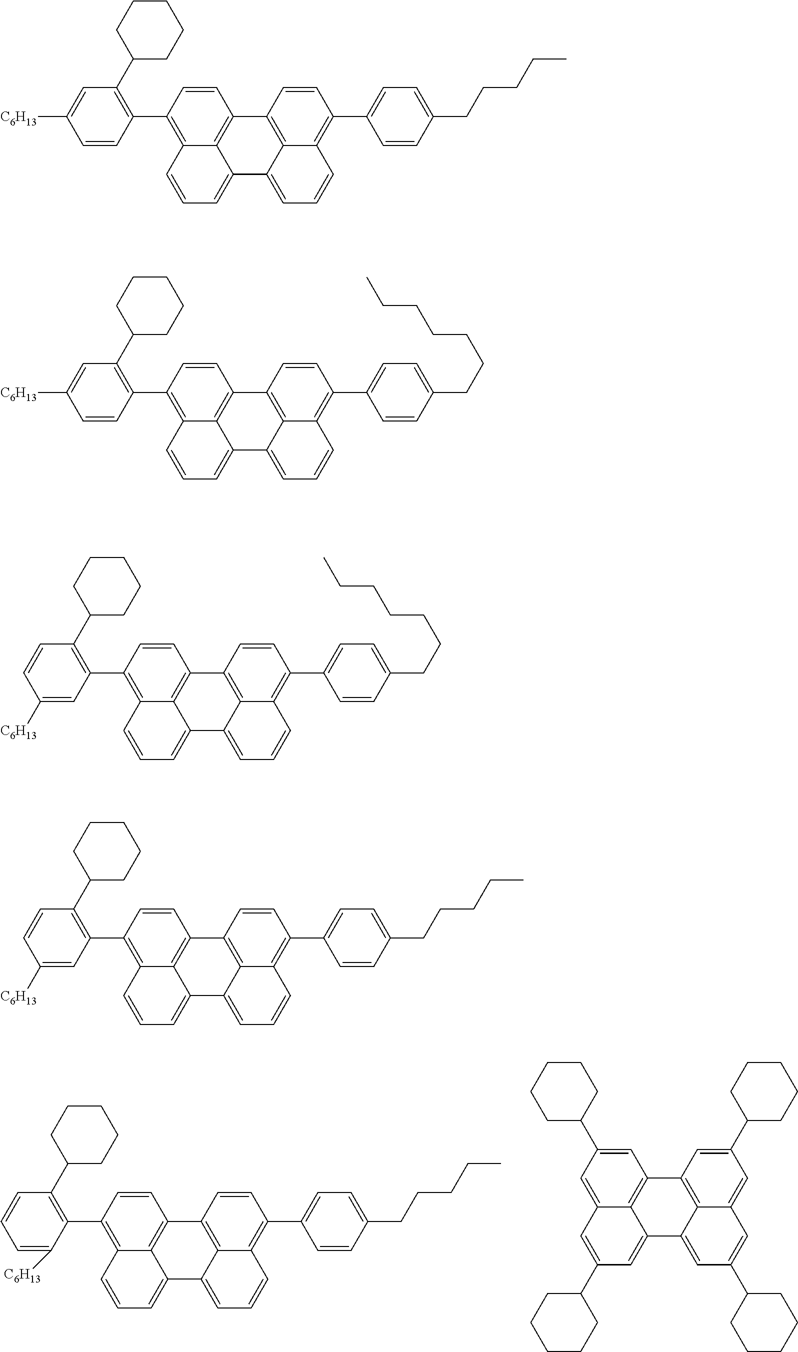

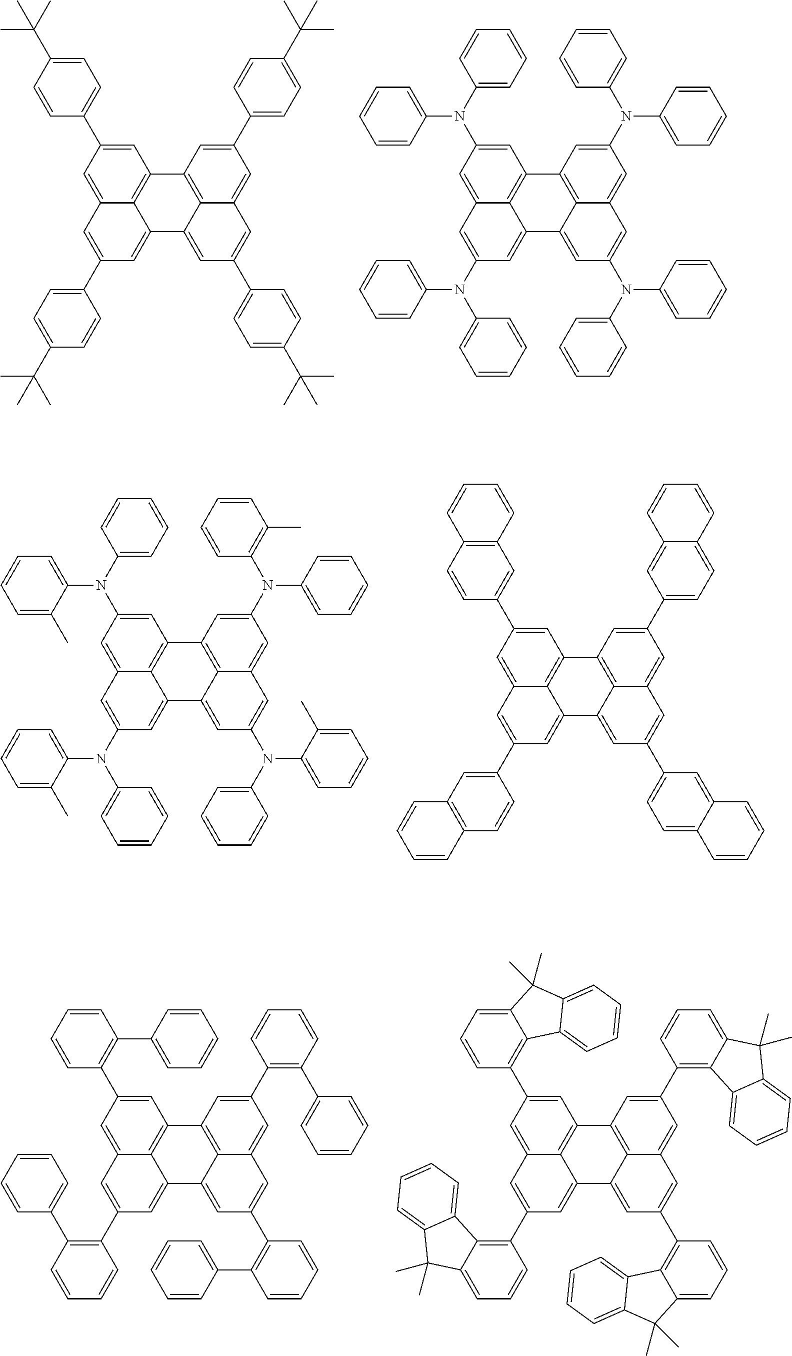

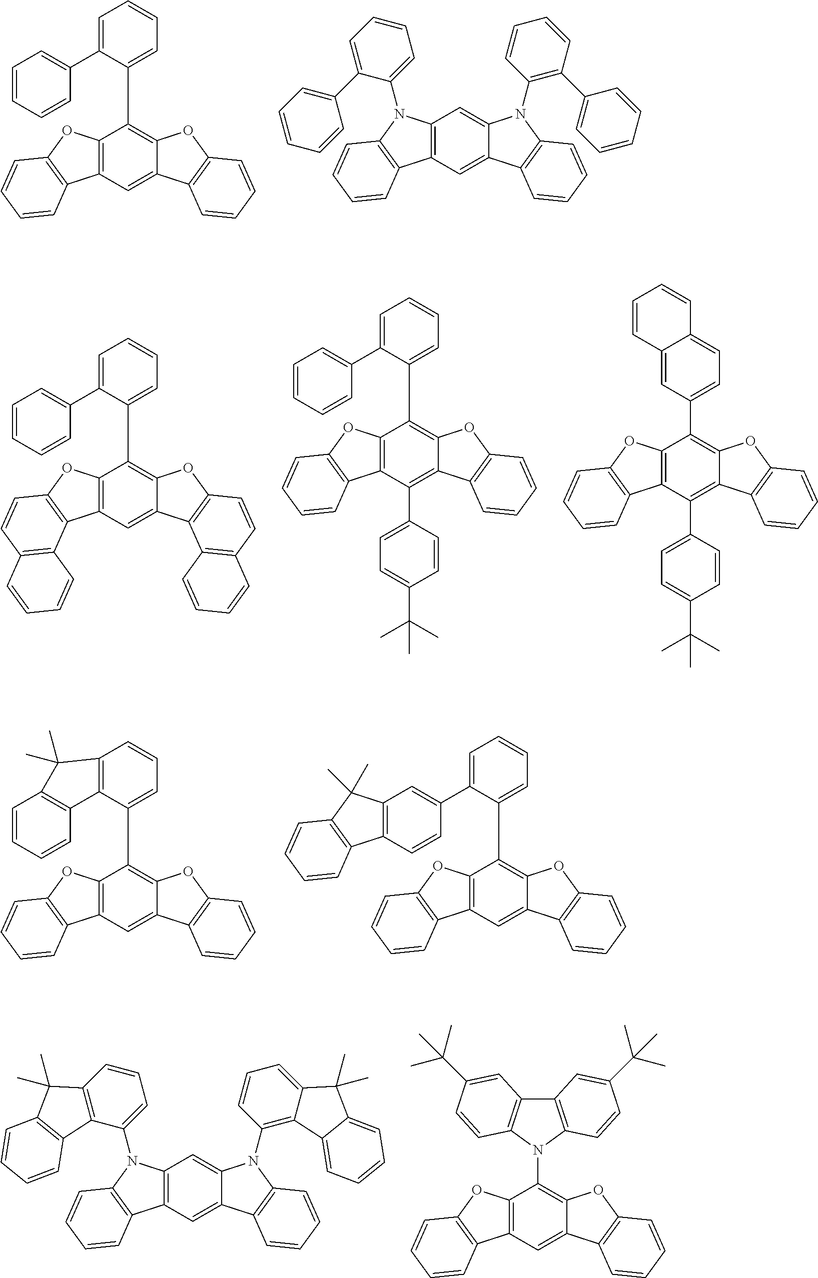

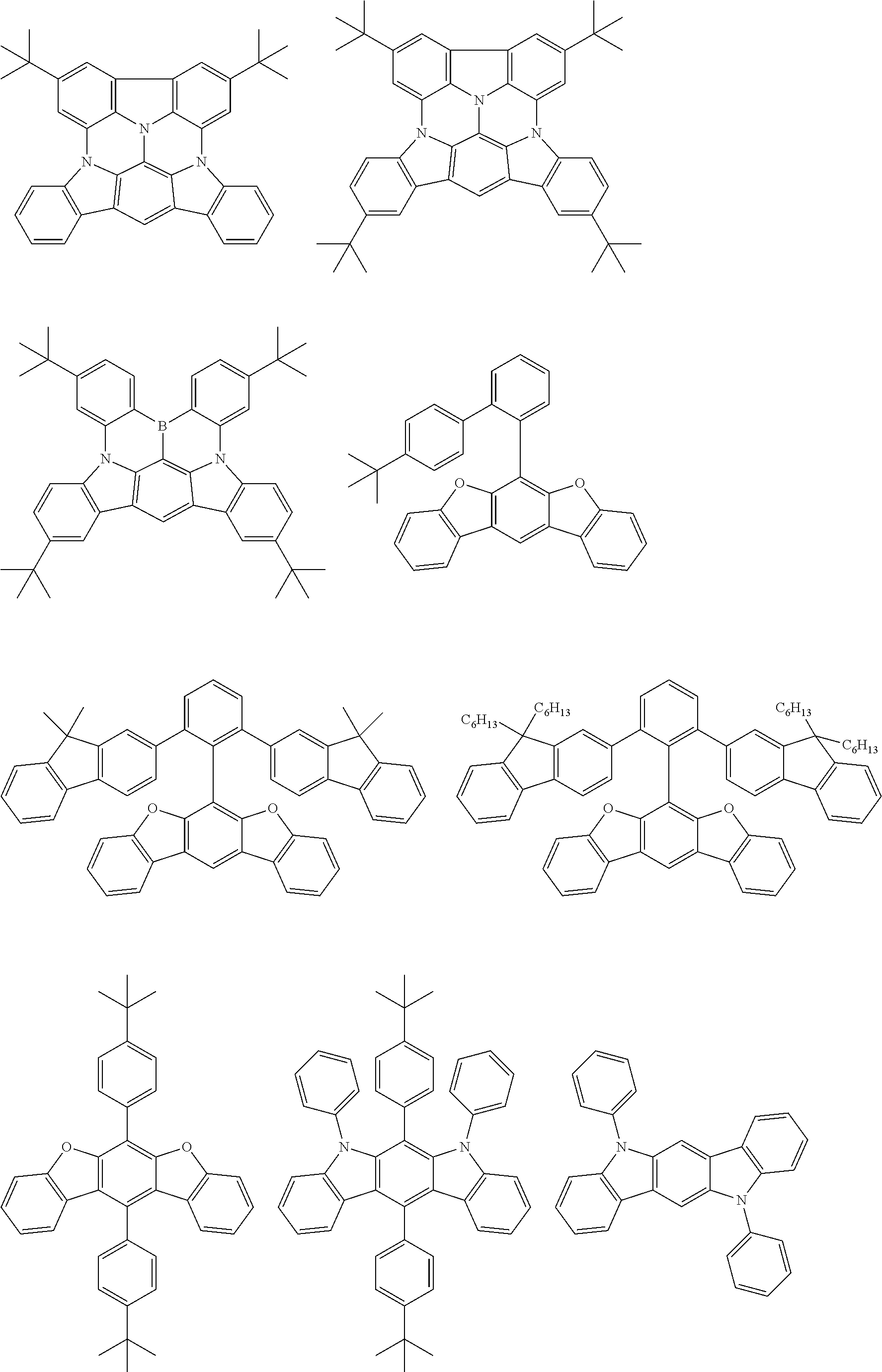

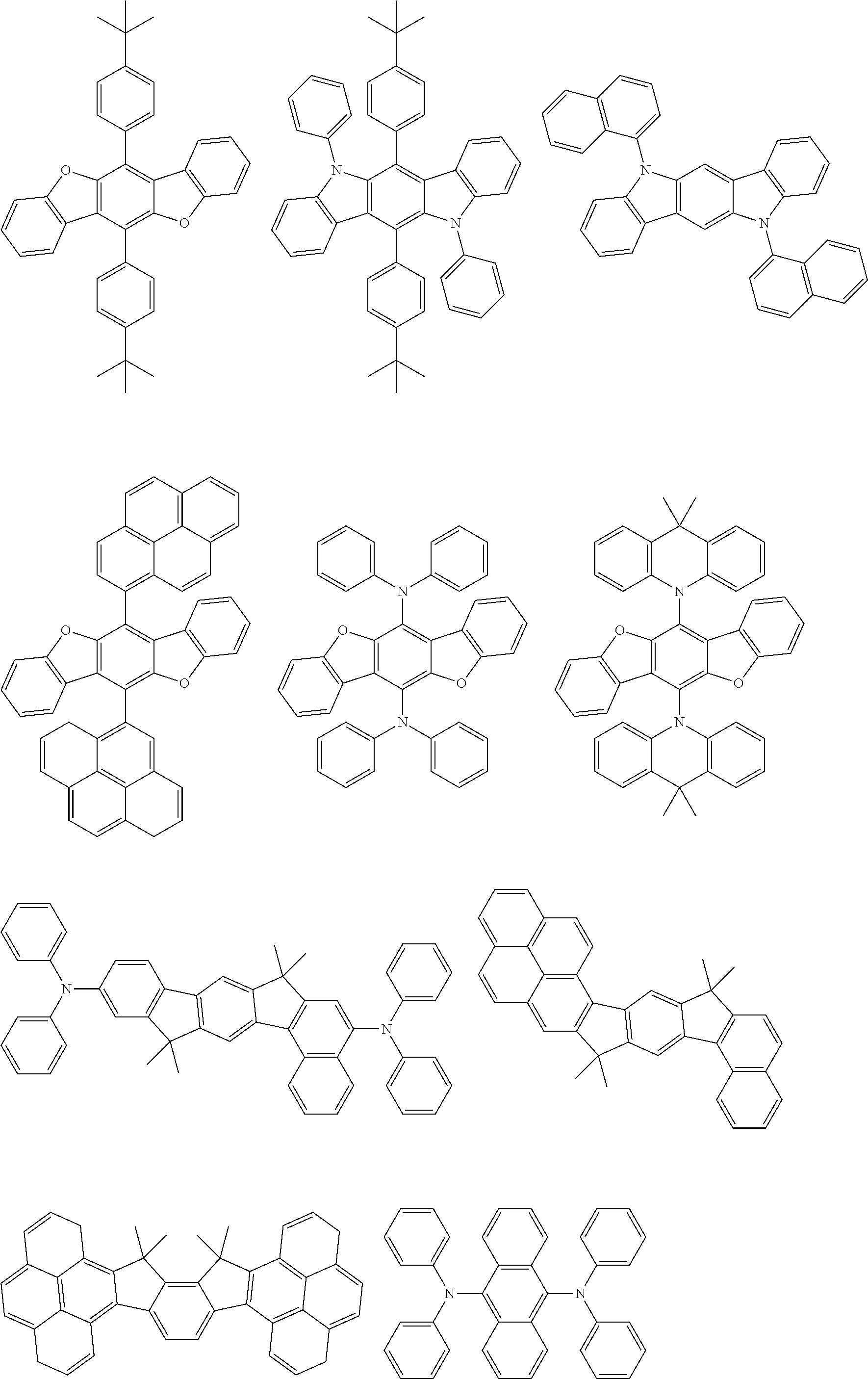

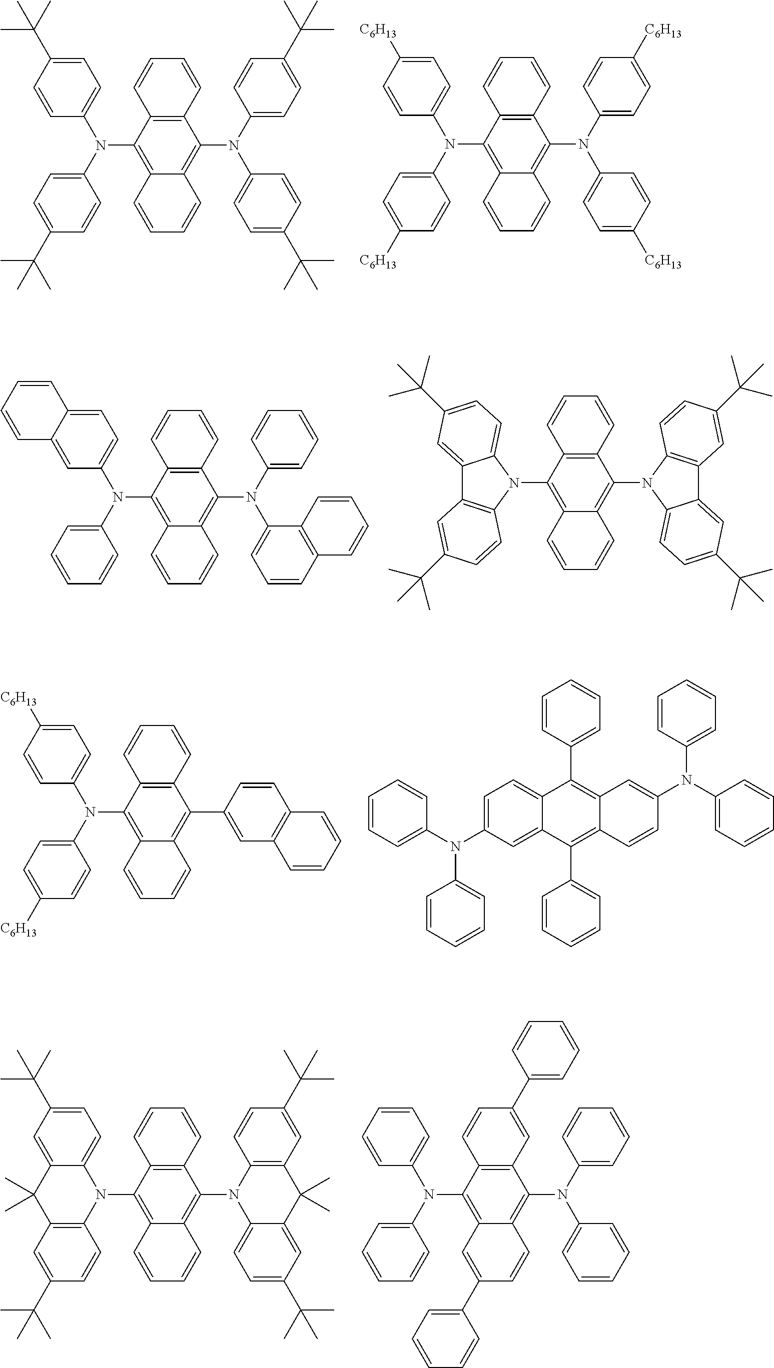

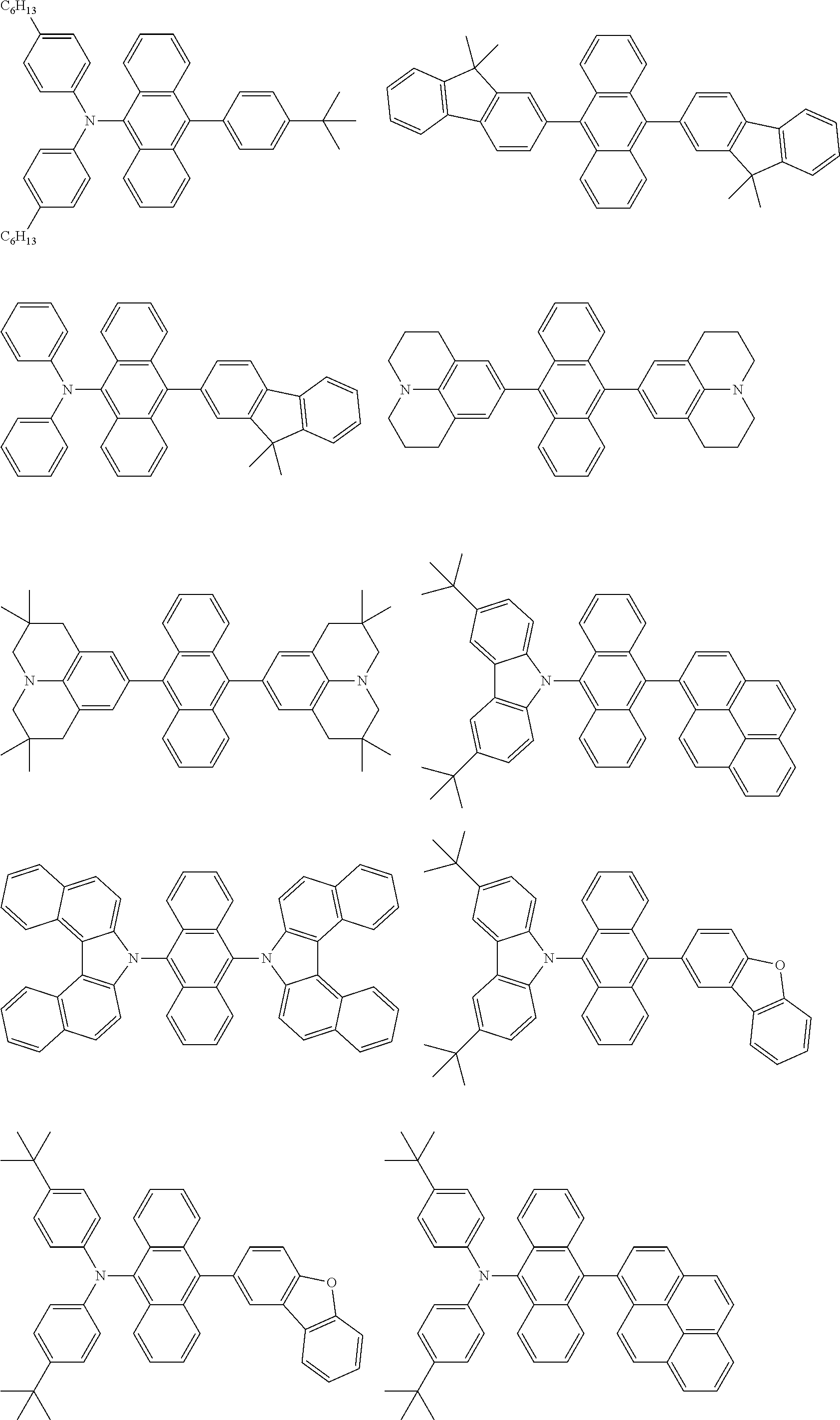

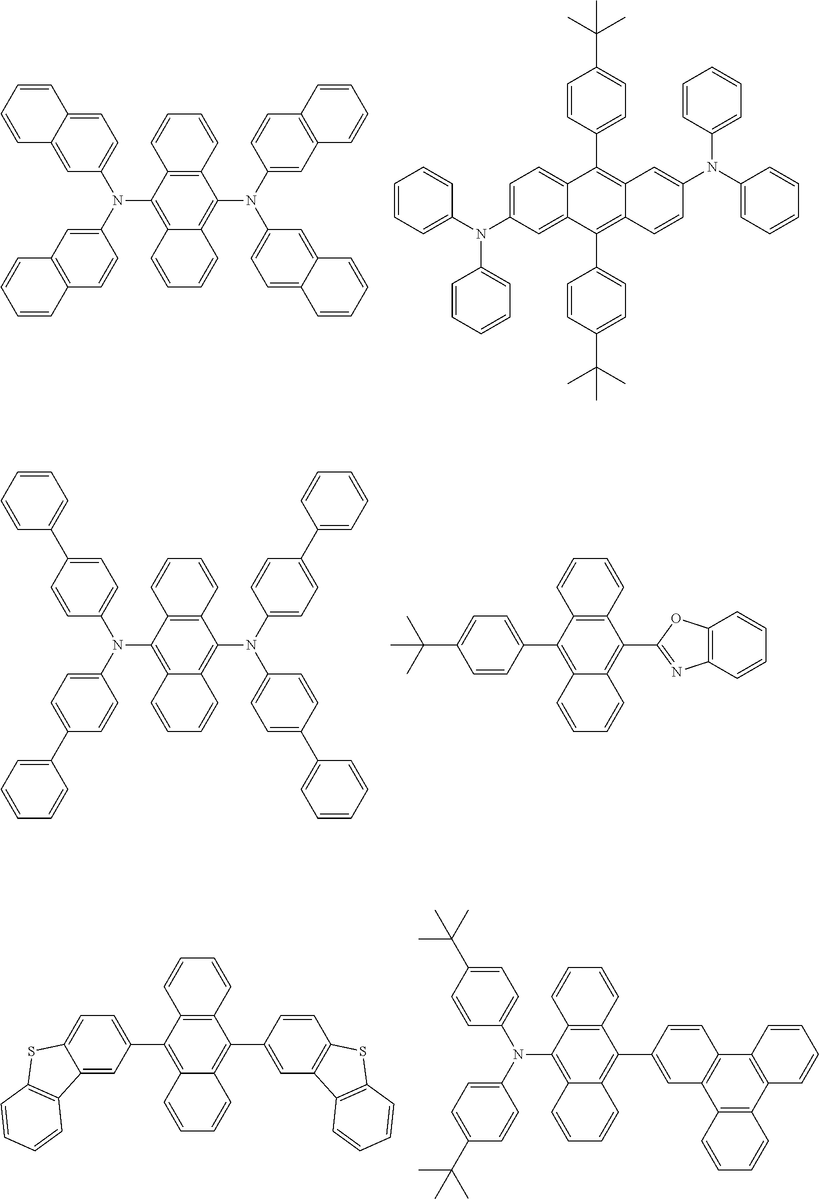

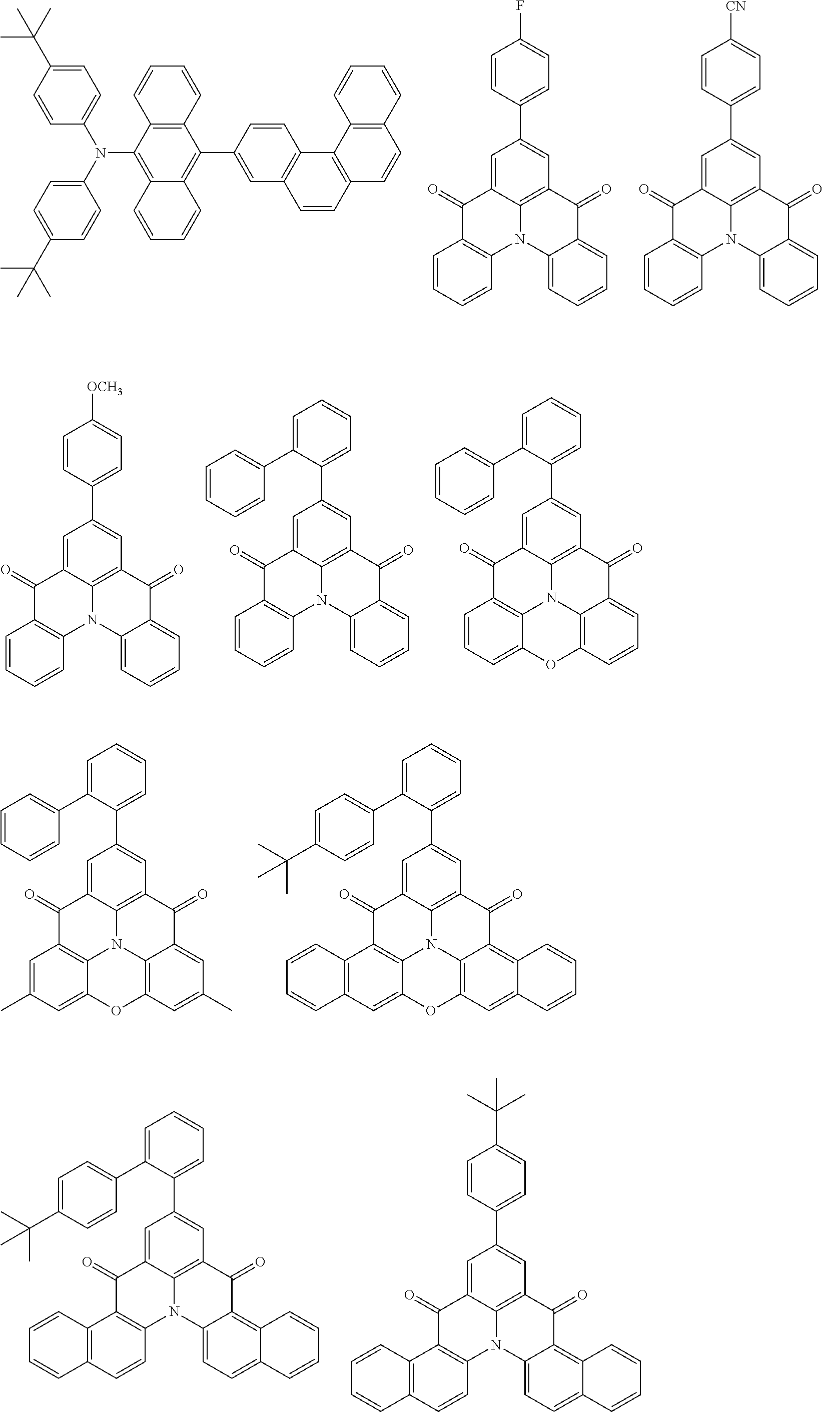

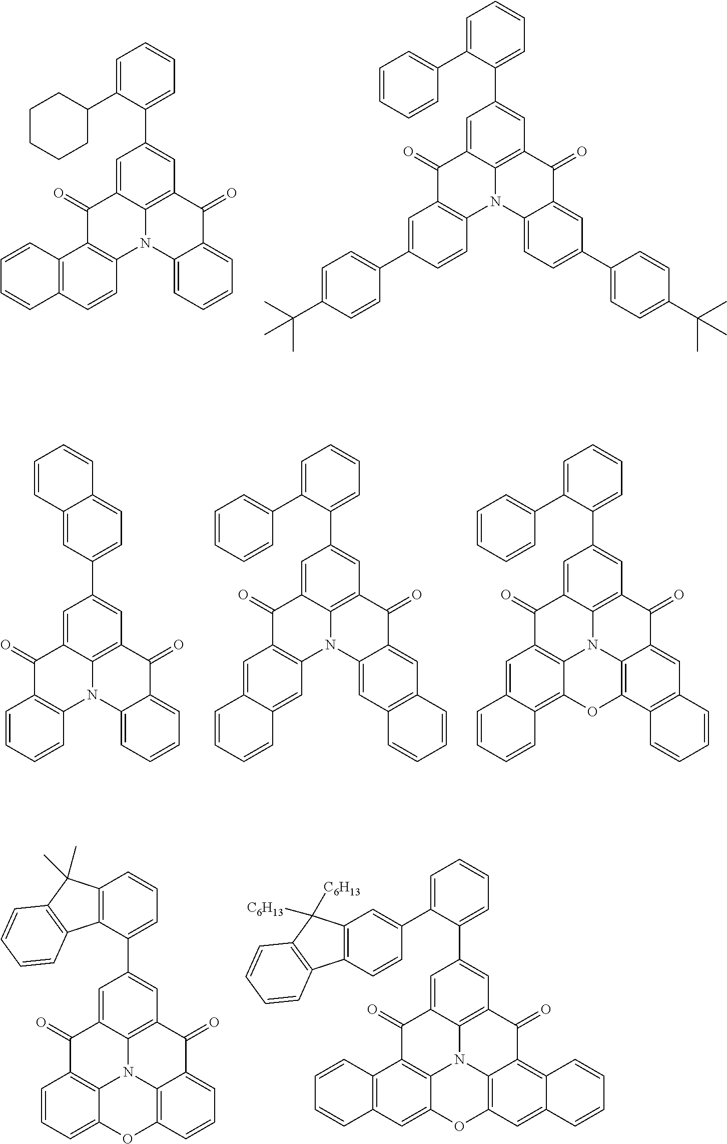

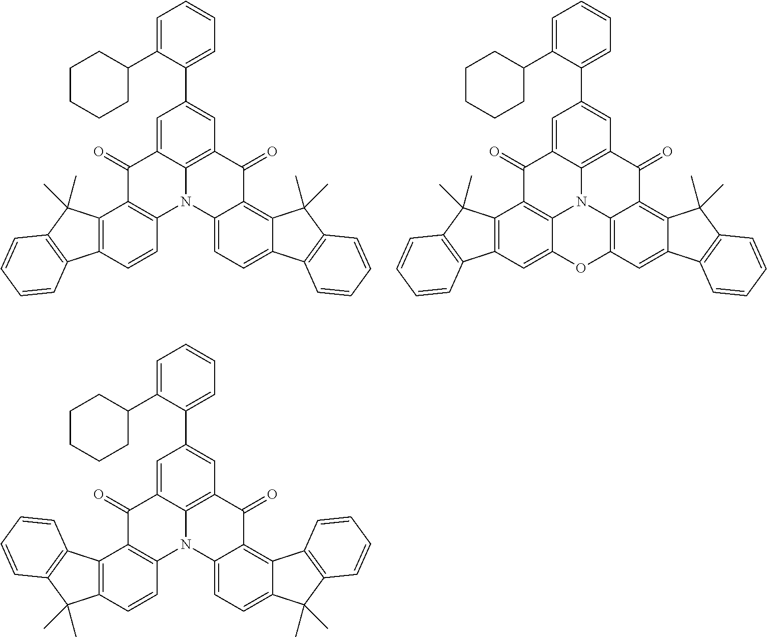

In some embodiments, the FWHM of the emission spectrum of the organic compound H≤70 nm, preferably ≤60 nm, more preferably ≤50 nm, further preferably ≤40 nm, and most preferably ≤35 nm.

In some embodiments, the organic compound H is a compound (i.e., Bodipy derivative) having the following structural formula:

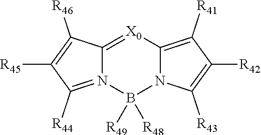

Where X₀ is CR₄₇ or N; R₄₁ to R₄₉ are independently selected from a hydrogen, an alkyl group, a cycloalkyl group, a heterocyclic group, an alkenyl group, a cycloalkenyl group, an alkynyl group, a hydroxy group, a mercapto group, an alkoxy group, an alkylthio group, an aryl ether group, an aryl thioether group, an aryl group, a heteroaryl group, a halogen, a cyano group, an aldehyde group, a carbonyl group, a carboxy group, an oxycarboxyl group, a carbamoyl group, an amino group, a nitro group, a silyl group, a siloxanyl group, a boronalkyl group, or a phosphorus oxide group; R₄₁-R₄₉ may form a fused ring and an aliphatic ring with the adjacent substituents therebetween.

In some embodiments, each of R₄₈ and R₄₉ is electron-withdrawing group. The suitable electron-withdrawing groups include, but not limited to, F, Cl, a cyano group, a partial/perfluorinated alkyl chain, or one of the following groups:

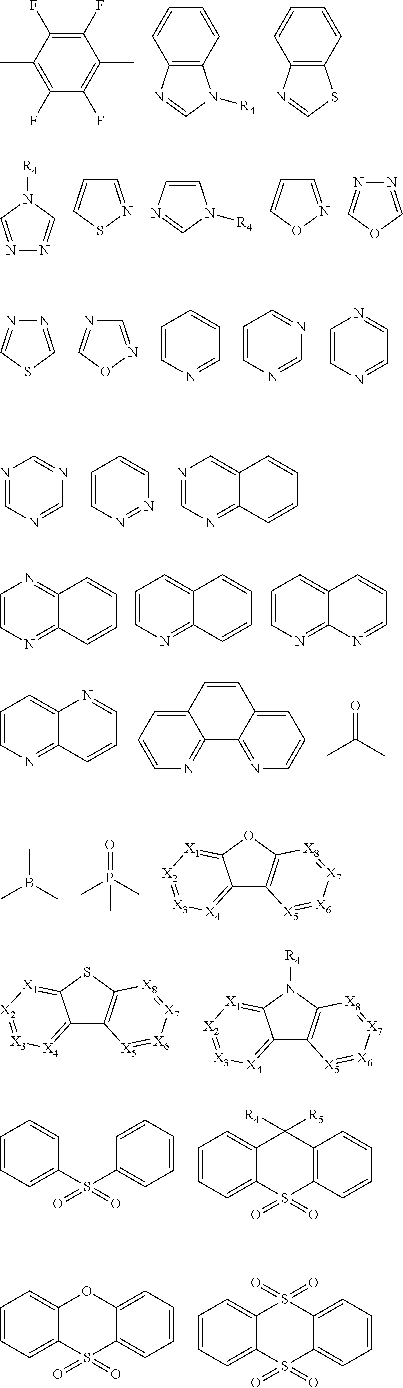

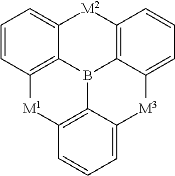

Where m is 1, or 2, or 3; each of X₁ to X₈ is CR₄ or N, and at least one of them is N; M 1, M 2, M³ independently represent N(R₄), C(R₄R₅), Si(R₄R₅), O, C═N(R₄), C═C(R₄R₅), P(R₄), P(═O)R₄, S, S═O, SO₂, or null; R₄ and R₅ are identically defined as the above-mentioned R¹.

Examples of suitable Bodipy derivatives include, but not limited to,

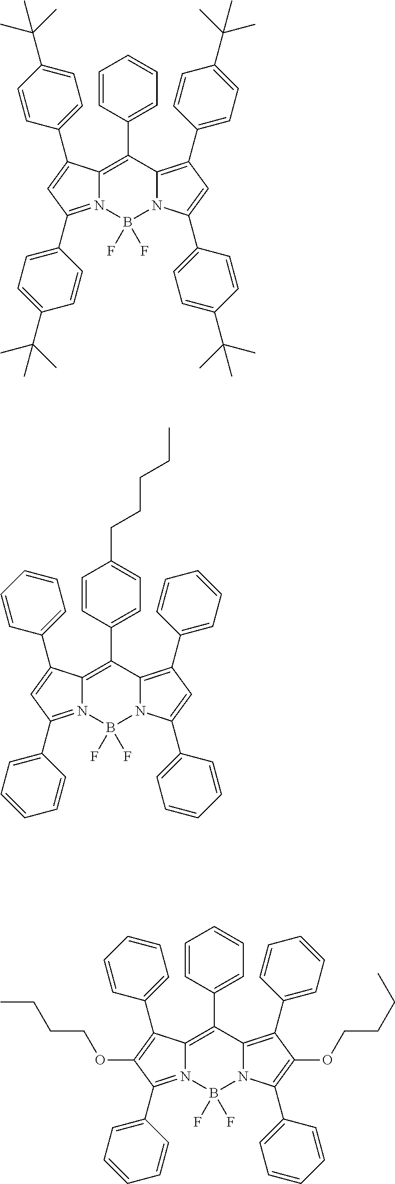

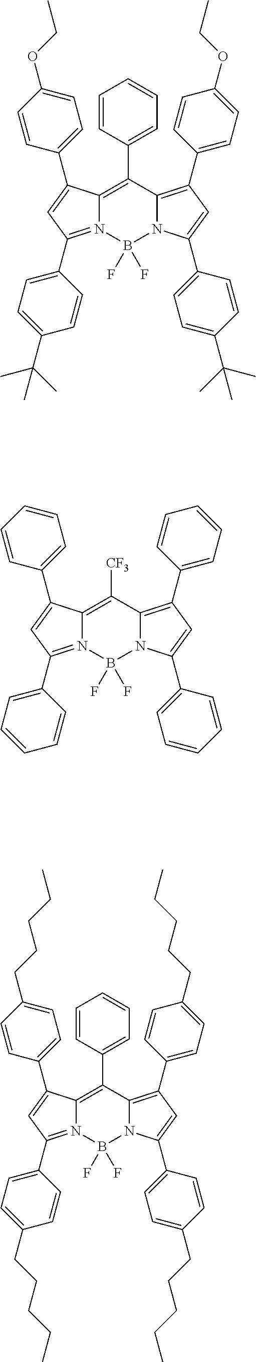

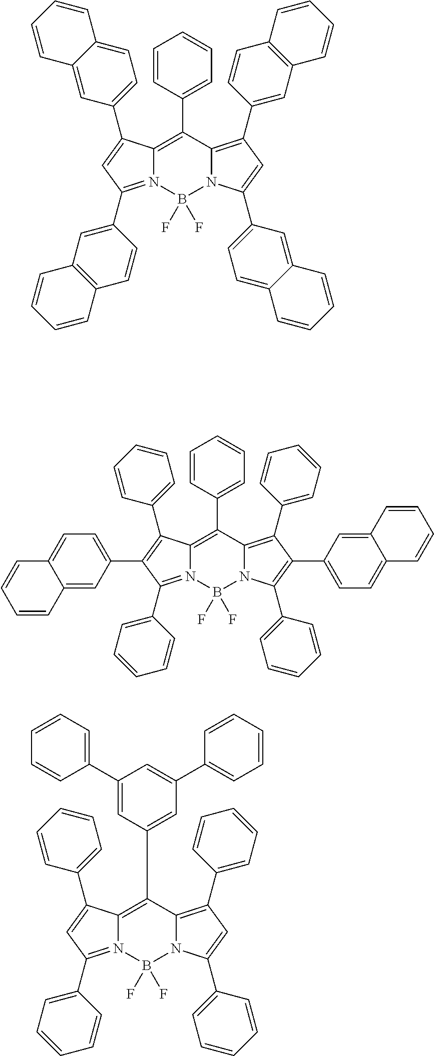

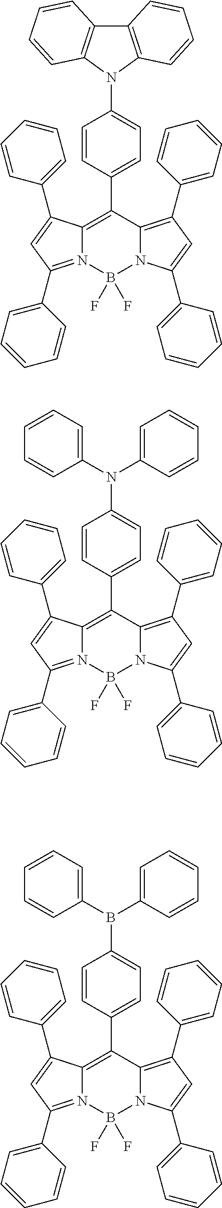

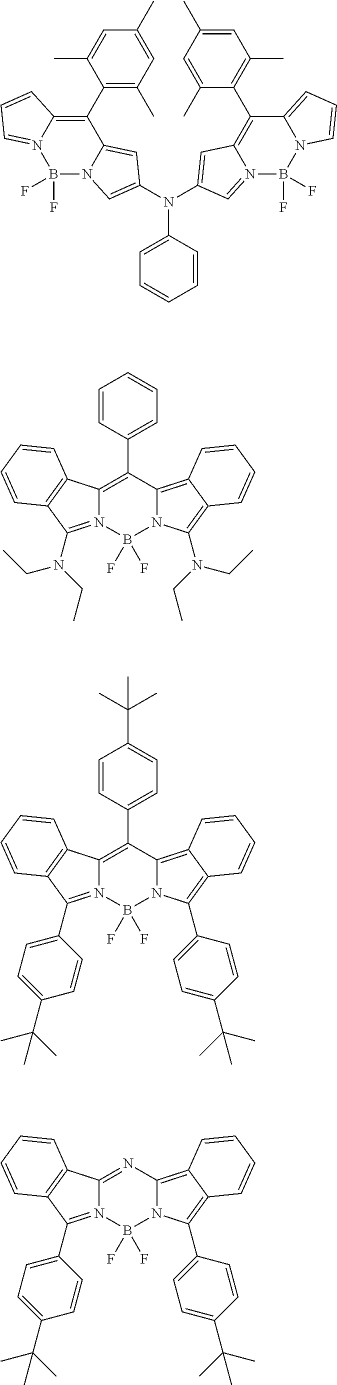

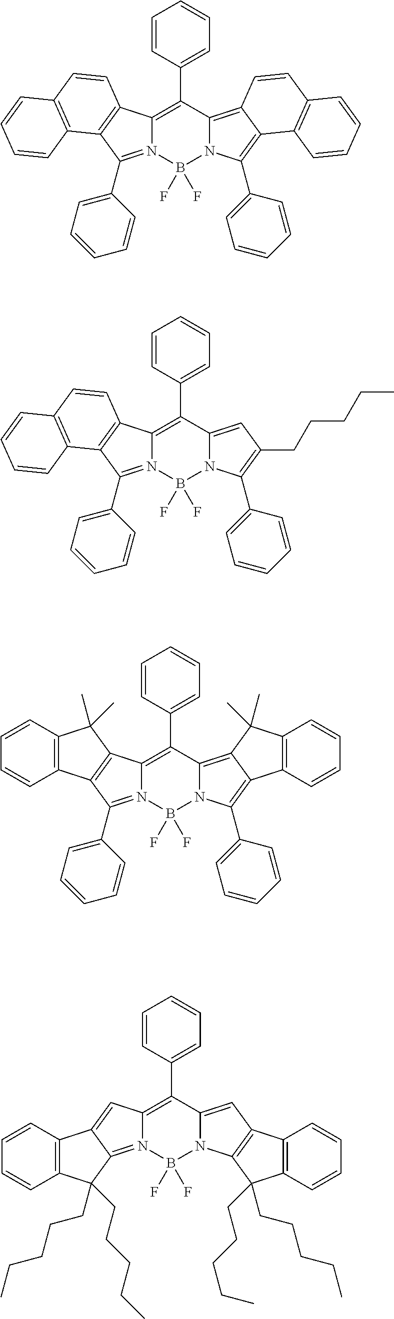

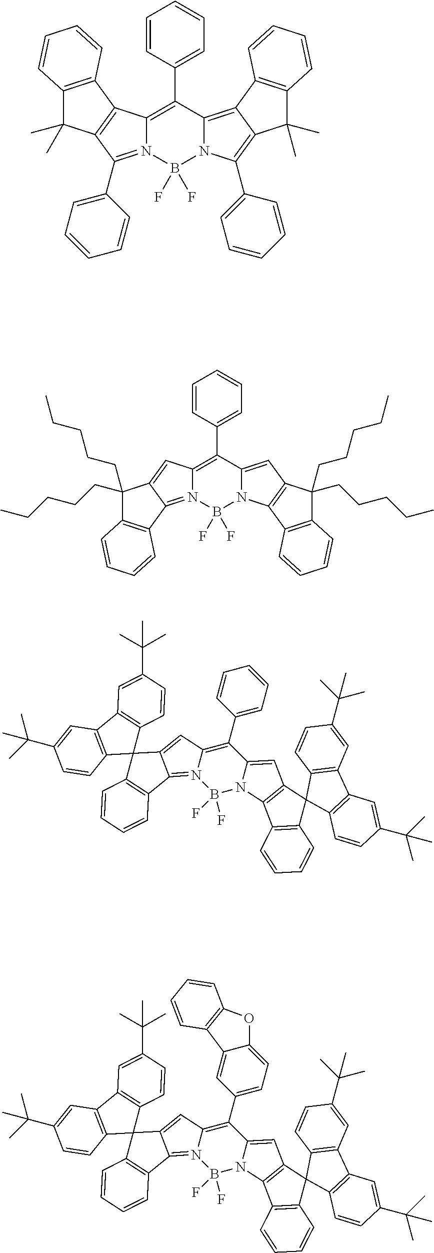

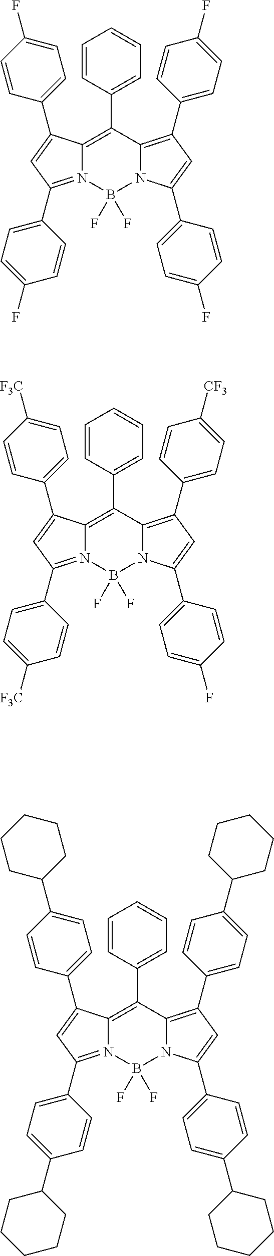

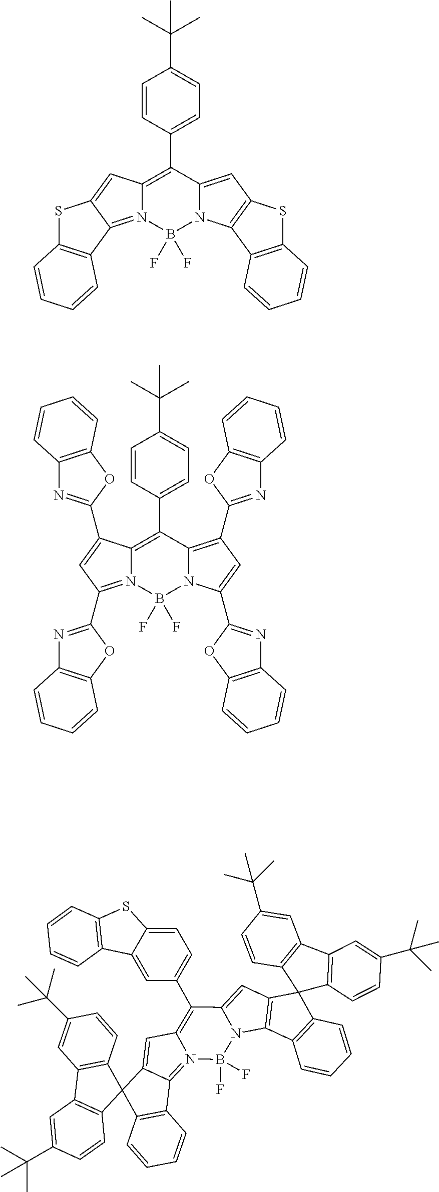

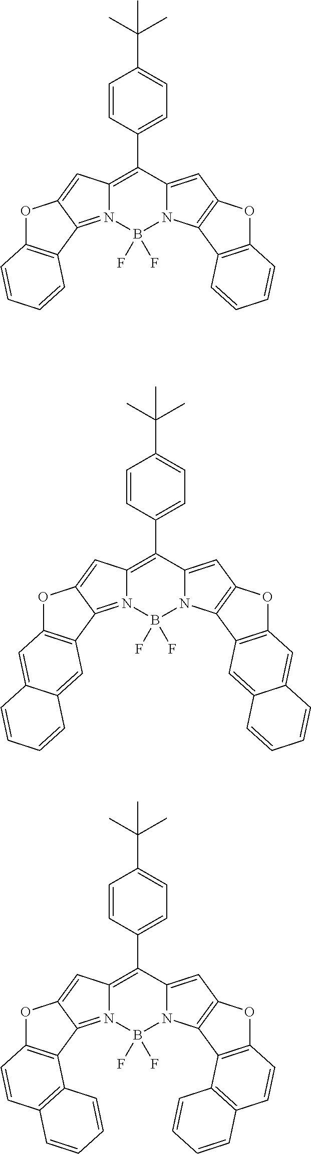

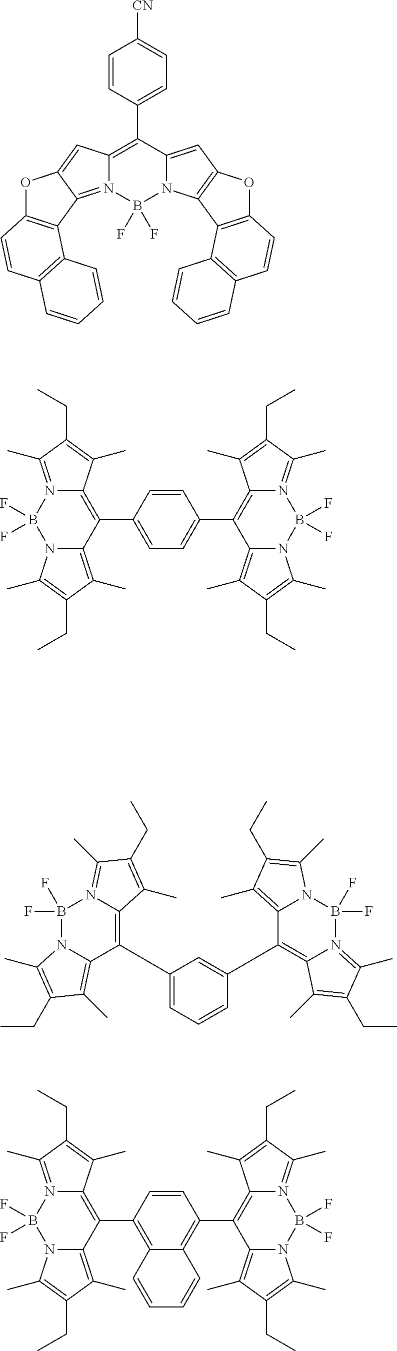

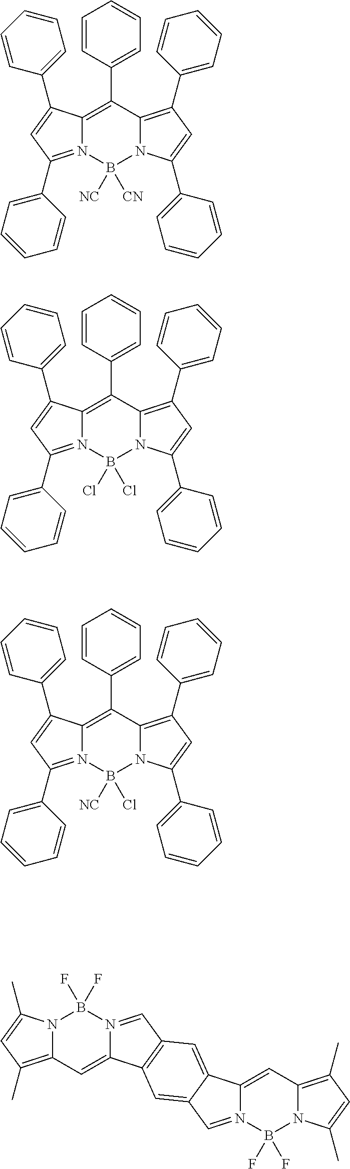

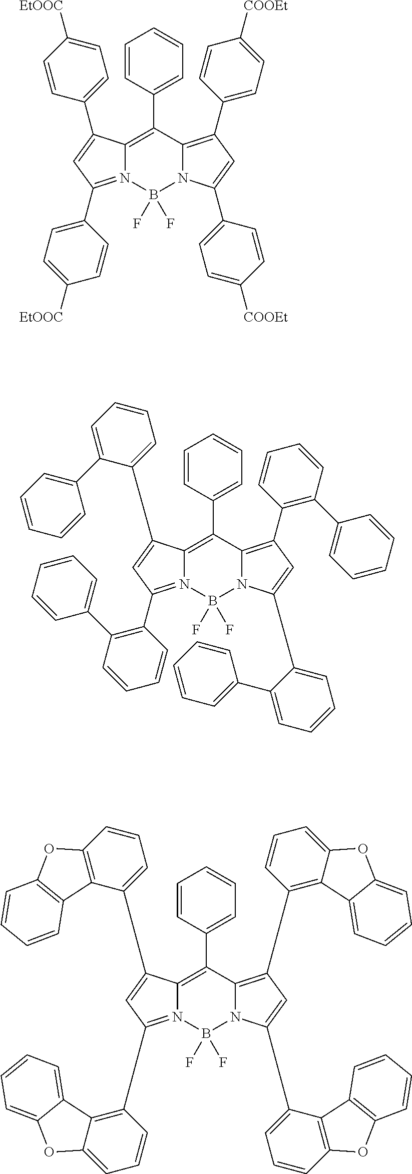

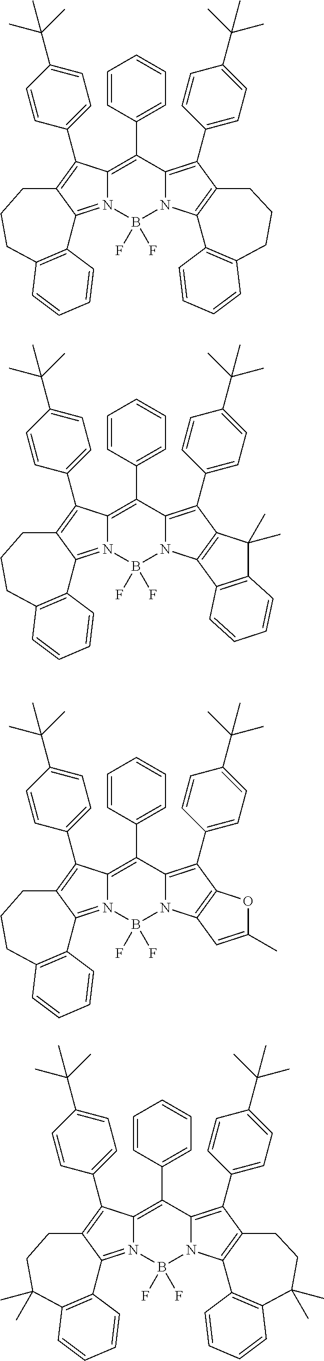

In some embodiments, the organic compound H comprises a structural unit of formula (1) or (2).

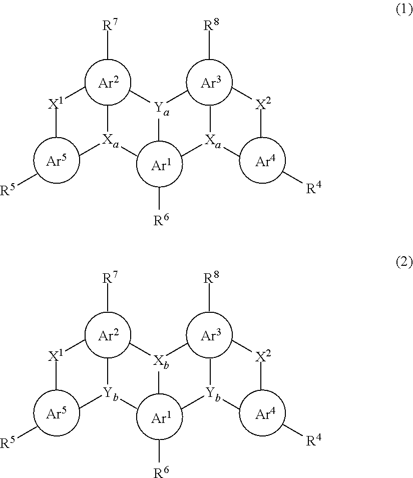

Where each of Ar¹ to Ar³ is independently selected from an aromatic group or a heteroaromatic group containing 5 to 24 ring atoms; each of Ar⁴ and Ar⁵ is independently selected from null, an aromatic group or a heteroaromatic group containing 5 to 24 ring atoms; when neither Ar⁴ nor Ar⁵ is null, each of Xₐ and X_{b} is independently selected from N, C(R⁹), or Si(R⁹); each of Yₐ and Y_{b} is independently selected from B, P═O, C(R⁹), or Si(R⁹); when Ar⁴ and/or Ar⁵ is null, each Yₐ is selected from B, P═O, C(R⁹), or Si(R⁹); each X_{b} is selected from N, C(R⁹), or Si(R⁹); each of Xₐ and Y_{b} is independently selected from N(R⁹), C(R⁹ R¹⁰), Si(R⁹ R¹⁰), C═O, 0, C═N(R⁹), C═C(R⁹ R¹⁰), P(R⁹), P(═O)R⁹, S, S═O, or SO₂; each of X¹ and X² is independently null or a bridging group; R⁴ to R¹⁰ are identically defined as the above-mentioned R¹.

In some embodiments, R⁴ to R¹⁰ are independently selected from the group consisting of —H, —D, a C₁-C₁₀ linear alkyl group, a C₁-C₁₀ linear alkoxy group, a C₁-C₁₀ linear thioalkoxy group, a C₃-C₁₀ branched/cyclic alkyl group, a C₃-C₁₀ branched/cyclic alkoxy group, a C₃-C₁₀ branched/cyclic thioalkoxy group, a C₃-C₁₀ branched or cyclic silyl group, a C₁-C₁₀ substituted ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 20 ring atoms, an aryloxy or heteroaryloxy group containing 5 to 20 ring atoms, and any combination thereof, where one or more R⁴ -R¹⁰ may form a monocyclic or polycyclic aliphatic or aromatic ring system with each other and/or with the rings bonded thereto.

The preferred embodiment of the organic compound H of formula (1) or (2) can be referred to three Chinese patent applications declared in the same period, with application No. CN202110370910.9, CN202110370866.1, CN202110370884.X. The patent document above are specially incorporated herein by reference in their entirety.

In the mixture as described herein, both the absorption spectrum of the inorganic nanoemitter E and the emission spectrum of the organic compound H have a large overlap, so that the efficient energy transfer (i.e., Förster resonance energy transfer (FRET)) can be realized therebetween.

In some embodiments, the emission spectrum of the mixture is derived exclusively from the inorganic nanoemitter E, i.e. a complete energy transfer is realized between the inorganic nanoemitter E and the organic compound H.

In some embodiments, the mixture comprises more than two organic compounds H.

In some embodiments, in the mixture as described herein, the weight ratio of the organic compound H to the inorganic nanoemitter E ranges from 50:50 to 99:1, preferably from 60:40 to 98:2, more preferably from 70:30 to 97:3, and most preferably from 80:20 to 95:5.

In some embodiments, the mixture further comprises an organic resin. For the purposes of the present disclosure, the organic resin refers to a resin prepolymer or a resin formed after the resin prepolymer is crosslinked or cured.

In some embodiments, the mixture comprises two or more organic resins.

The organic resins suitable for the present disclosure include, but not limited to: polystyrene, polyacrylate, polymethacrylate, polycarbonate, polyurethane, polyvinylpyrrolidone, polyvinyl acetate, polyvinyl chloride, polybutylene, polyethylene glycol, polysiloxane, polyacrylate, epoxy resin, polyvinyl alcohol, polyacrylonitrile, polyvinylidene chloride (PVDC), polystyrene-acrylonitrile (SAN), polybutylene terephthalate (PBT), polyethylene terephthalate (PET), polyvinyl butyrate (PVB), polyvinyl chloride (PVC), polyamide, polyoxymethylene, polyimide, polyetherimide, and mixtures thereof.

Further, the organic resins suitable for the present disclosure include, but not limited to, those prepared by the homopolymerization or copolymerization from the following monomers (resin prepolymers): styrene derivatives, acrylate derivatives, acrylonitrile derivatives, acrylamide derivatives, vinyl ester derivatives, vinyl ether derivatives, maleimide derivatives, conjugated diene derivatives.

Examples of styrene derivatives include, but not limited to alkylstyrenes, such as α-methylstyrene, o-, m-, p-methylstyrene, p-butyl styrene; especially 4-tert-butylstyrene, alkoxystyrene, such as p-methoxystyrene, p-butoxystyrene, p-tert-butoxystyrene.

Examples of acrylate derivatives include, but not limited to methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, sec-butyl acrylate, sec-butyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene glycol acrylate, methoxydiethylene glycol methacrylate, methoxytriethylene glycol acrylate, methoxytriethylene glycol methacrylate, methoxypropylene glycol acrylate, methoxypropylene glycol methacrylate, methoxy dipropylene glycol acrylate, methoxydipropylene glycol methacrylate, isobornyl acrylate, isobornyl methacrylate, dicyclopentadiene acrylate, dicyclopentadiene methacrylate, adamantane (meth) acrylate, norbornene (meth) acrylate, 2-hydroxy-3-phenoxypropyl acrylate, 2-hydroxy-3-phenoxypropyl methacrylate, glyceryl monoacrylate, and glyceryl monostearate; 2-aminoethyl acrylate, 2-aminoethyl methacrylate, 2-dimethylaminoethyl acrylate, 2-dimethylaminoethyl methacrylate, N,N-dimethylaminoethyl (meth) acrylic acid, N,N-diethylaminoethyl (meth) acrylate, 2-dimethylaminopropyl methacrylate, 3-aminopropyl acrylate, 3-aminopropyl methacrylate, N,N-dimethyl-1,3-propane diamine (meth) acrylate, 3-dimethylaminopropyl acrylate, 3-dimethylaminopropyl methacrylate, glycidyl acrylate, and glycidyl methacrylate.

Examples of the acrylonitrile derivatives include, but not limited to acrylonitrile, methacrylonitrile, α-chloroacrylonitrile, and vinylidene cyanide.

Examples of acrylamide derivatives include, but are not limited to acrylamide, methacrylamide, α-chloroacrylamide, N-2-hydroxyethyl acrylamide, and N-2-hydroxyethyl methacrylamide.

Examples of vinyl ester derivatives include, but not limited to vinyl acetate, vinyl propionate, vinyl butyrate, and vinyl benzoate.

Examples of vinyl ether derivatives include, but not limited to vinyl methyl ether, vinyl ethyl ether, and allyl glycidyl ether.

Examples of maleimide derivatives include, but not limited to maleimide, benzylmaleimide, N-phenylmaleimide, and N-cyclohexylmaleimide.

Examples of conjugated diene derivatives include, but not limited to 1,3-butadiene, isoprene, and chloroprene.

The homopolymers or copolymers can be prepared by free-radical polymerization, cationic polymerization, anionic polymerization, or organometallic catalysis polymerization (for example Ziegler-Natta catalysis). The polymerization process may be suspension polymerization, emulsion polymerization, solution polymerization, or bulk polymerization.

The number average molecualr weight Mn (as determined by GPC) of the organic resins is generally in the range of 10 000 g/mol to 1 000 000 g/mol, preferably in the range of 20 000 g/mol to 750 000 g/mol, more preferably in the range of 30 000 g/mol to 500 000 g/mol.

In some embodiments, at least one of the organic resin is a thermosetting resin or an UV curable resin. In some embodiments, the organic resin is cured by a method that will enable roll-to-roll processing.

Thermosetting resins require curing in which they undergo an irreversible process of molecular cross-linking, which makes the resin non-fusible. In some embodiments, the thermosetting resin is an epoxy resin, a phenolic resin, a vinyl resin, a melamine resin, a urea-formaldehyde resin, an unsaturated polyester resin, a polyurethane resin, an allyl resin, an acrylic resin, a polyamide resin, a polyamide-imide resin, a phenol-amide polycondensation resin, an urea-melamine polycondensation resin, or combinations thereof.

In some embodiments, the thermosetting resin is an epoxy resin. The epoxy resins are easy to cure and do not give off volatiles or generate by-products from a wide range of chemicals. The epoxy resins can also be compatible with most substrates and tend to readily wet surfaces. See also Boyle, M. A. et al., “Epoxy Resins”, Composites, Vol.21, ASM Handbook, pages 78-89 (2001).

In some embodiments, the organic resin is a silicone thermosetting resin. In some embodiments, the silicone thermosetting resin is 0E6630A or 0E6630B (Dow Corning Corporation (Auburn, Michigan.)).

In some embodiments, a thermal initiator is used. In some embodiments, the thermal initiator is AIBN[2,2′-azobis(2-methylpropionitrile)] or benzoyl peroxide.

The UV curable resin is a polymer that will cure and rapidly harden upon exposure to light of a specific wavelength. In some embodiments, the UV curable resin is a resin having a free radical polymerization group, and a cationic polymerizable group as functional groups; the radical polymerizable group is such as (meth)acryloyloxy group, vinyloxy group, styryl group, or vinyl group. The cationically polymerizable group is such as epoxy group, thioepoxy group, vinyloxy group, or oxetanyl group. In some embodiments, the UV curable resin is a polyester resin, a polyether resin, a (meth)acrylic resin, an epoxy resin, a polyurethane resin, an alkyd resin, a spiroacetal resin, a polybutadiene resin, or a thiolene resin.

In some embodiments, the UV curable resin is selected from polyurethane acrylate, allyloxy diacrylate, bis (acryloyloxyethyl) hydroxyisocyanurate, bis (acryloyloxyneopentyl glycol) adipate, bisphenol A diacrylate, bisphenol A dimethacrylate, 1,4-butanediol diacrylate, 1,4-butanediol dimethacrylate, 1,3-butanediol diacrylate, 1,3-butanediol dimethacrylate, dicyclopentyl diacrylate, diethylene glycol diacrylate, diethylene glycol dimethacrylate, dipentaerythritol hexaacrylate, dipentaerythritol monohydroxy pentacrylate, bis(trimethylolpropane) tetraacrylate, triethylene glycol dimethacrylate, glyceryl methacrylate, 1,6-hexanediol diacrylate, neopentyl glycol dimethacrylate, neopentyl glycol hydroxypivalonate, pentaerythritol triacrylate, pentaerythritol tetraacrylate, dimethacrylate, polyethylene glycol diacrylate, polypropylene glycol diacrylate, tetraethylene glycol diacrylate, tetrabromobisphenol A diacrylate, triethylene glycol divinyl ether, glycerol diacrylate, trimethylolpropane triacrylate, tripropylene glycol diacrylate, tris (acryloyloxyethyl) isocyanurate, triacrylate, diacrylate, propyl acrylate, vinyl-terminated polydimethylsiloxane, vinyl-terminated diphenyl siloxane-dimethyl siloxane copolymer, vinyl-terminated polyphenyl methyl siloxane, vinyl-terminated difluoromethyl siloxane-dimethyl siloxane copolymer, vinyl-terminated diethyl siloxane-dimethyl siloxane copolymer, vinyl methyl siloxane, monomethacryloxypropyl-terminated polydimethylsiloxane, monovinyl-terminated polydimethylsiloxane, monoallyl-mono-trimethylsilyloxy-terminated polyethylene oxide, or any combination thereof.

In some embodiments, the UV curable resin is a mercapto functional compound that can be cross-linked under UV curing conditions with an isocyanate, an epoxy resin, or an unsaturated compound. In some embodiments, the mercapto functional compound is a polythiol. In some embodiments, the polythiol is selected from: pentaerythritol tetrakis(3-mercaptopropionate) (PETMP), trimethylolpropane tris(3-mercaptopropionate) (TMPMP), ethylene glycol bis(3-mercaptopropionate) (GDMP); tris [25-(3-mercapto-propionyloxy)ethyl] isocyanurate (TEMPIC), dipentaerythritol hexa(3-mercaptopropionate) (Di-PETMP), ethoxylated trimethylolpropane tri(3-mercaptopropionate) (ETMP1300 and ETTMP700), polycaprolactone tetra(3-mercaptopropionate) (PCL4MP1350), pentaerythritol tetramercaptoacetate (PETMA), trimethylolpropane trimercaptoacetate (TMPMA), or ethylene glycol dimercaptoacetate (GDMA). These compounds are sold under the trade name THIOCURE ® by Bruno Bock (Malsacht, Germany).

In some embodiments, the UV curable resin further comprises photoinitiator. The photoinitiator will initiate crosslinking and/or curing reactions of the photosensitive material during exposure to light. In some embodiments, the photoinitiator is a compound such as acetophenone-based, benzoin-based, or thidrone-based that initiate the polymerization, crosslinking and curing of monomers.

In some embodiments, the UV curable resin comprises mercapto-functional compounds, methacrylates, acrylates, isocyanates, or any combination thereof. In some embodiments, the UV curable resin comprises polythiols, methacrylates, acrylates, isocyanates, or any combination thereof.

In some embodiments, the photoinitiator is MINS-311RM (Minuta Technology Co., Ltd (Korea)).

In some embodiments, the photoinitiator is Irgacure® 127, Irgacure® 184, Irgacure® 184D, Irgacure® 2022, Irgacure® 2100, Irgacure® 250, Irgacure® 270, Irgacure® 2959, Irgacure® 369, Irgacure® 369EG, Irgacure® 379, Irgacure® 500, Irgacure® 651, Irgacure® 754, Irgacure® 784, Irgacure® 819, Irgacure® 819DW, Irgacure® 907, Irgacure® 907FF, Irgacure® Oxe01, Irgacure® TPO-L, Irgacure® 1173, Irgacure® 1173D, Irgacure® 4265, Irgacure® BP, or Irgacure® MBF (BASF Corporation (Wyandotte, Michigan)).

In some embodiments, the photoinitiator is TPO (2,4,6-trimethylbenzoyl-diphenyl-oxide) or MBF (methyl benzoyl formate).

In some embodiments, the weight ratio of the at least one of the organic resin is from 20 wt % to 99 wt %.

In some embodiments, the weight percentage of organic resin in the formulation is about 20% to about 99%, about 20% to about 95%, about 20% to about 90%, about 20% to about 85%, about 20% to about 80%, about 20% to about 70%, about 20% to about 60%, about 40% to about 99%, about 40% to about 95%, about 40% to about 90%, about 40% to about 85%, about 40% to about 80%, about 40% to about 70%, about 70% to about 99%, about 70% to about 95%, about 70% to about 90%, about 70% to about 85%, about 70% to about 80%, about 80% to about 99%, about 80% to about 95%, about 80% to about 90%, about 80% to about 85%, about 85% to about 99%, about 85% to about 95%, about 85% to about 90%, about 90% to about 99%, about 90% to about 95%, or about 95% to about 99%.

In another aspect, the present disclosure also provides a formulation comprising a mixture as described herein, and at least one solvent.

In some embodiments, the formulation as described herein is a solution.

In some embodiments, the formulation as described herein is a dispersion.

The formulations as described herein in the embodiments of the present invention may comprise the inorganic nanoemitter E of 0.01 wt % to 20 wt %, preferably 0.1 wt % to 20 wt %, more preferably 0.2 wt % to 20 wt %, and most preferably 2 wt % to 15 wt %.

Using the formulation as described herein, the color conversion layer may be fabricated by ink-jet printing, transfer printing, photolithography, etc. In this case, the compound (i.e., the color conversion material) needs to be dissolved alone or together with other materials in a resin (prepolymer) and/or an organic solvent, to form the ink. The mass concentration of the compound (i.e. the color conversion material) in the ink is not less than 0.1 wt %. The color conversion ability of the color conversion layer can be tuned by adjusting the concentration of the color conversion material in the ink and the thickness of the color conversion layer. In general, the higher the concentration of the color conversion material or the thickness of the layer, the higher the color conversion efficiency of the color conversion layer would be.

In some embodiments, the at least one of the solvent is selected from water, alcohols, esters, aromatic ketones, aromatic ethers, aliphatic ketones, aliphatic ethers, borates, phosphorates, or mixtures of two or more of them.

In some embodiments, the suitable and preferred solvents include aliphatics, alicyclics, aromatics, amines, thiols, amides, nitriles, esters, ethers, polyethers, alcohols, diols, or polyols.

In some embodiments, the alcohol represents a solvent of the suitable class. The preferred alcohols include alkylcyclohexanol, especially methylated aliphatic alcohol, naphthol, etc.

Other examples of the suitable alcohol solvents include dodecanol, phenyltridecanol, benzyl alcohol, ethylene glycol, ethylene glycol methyl ether, glycerol, propylene glycol, propylene glycol 1-ethoxy-2-propanol, etc.

The solvent may be used alone or as a mixture of two or more organic solvents.

Further, examples of organic solvents, include(but are not limited to): methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 3 -phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, naphthane, indene, and/or any mixture thereof.

In some embodiments, the organic solvent of the formulation is selected from aromatic, heteroaromatic, ester, aromatic ketone, aromatic ether, aliphatic ketone, aliphatic ether, cycloaliphatic, alicyclic or olefin compounds, borate, phosphorate, or a mixture of two or more of them.

Examples of aromatic or heteroaromatic solvents as described herein include, but not limited to: 1-tetralone, 3-phenoxytoluene, acetophenone, 1-methoxynaphthalene, p-diisopropylbenzene, amylbenzene, tetrahydronaphthalene, cyclohexylbenzene, chloronaphthalene, 1,4-dimethylnaphthalene, 3-isopropylbiphenyl, p-methylcumene, dipentylbenzene, o-diethylbenzene, m-diethylbenzene, p-diethylbenzene, 1,2,3,4-tetramethyl benzene, 1,2,3,5-tetramethyl benzene, 1,2,4,5-tetramethyl benzene, butylbenzene, dodecyl benzene, 1-methylnaphthalene, 1,2,4-trichlorobenzene, 1,3-dipropoxybenzene, 4,4-difluorodiphenylmethane, diphenyl ether, 1,2-dimethoxy-4-(1-propenyl) benzene, diphenylmethane, 2-phenylpyridine, 3-phenylpyridine, 2-phenoxymethyl ether, 2-phenoxytetrahydrofuran, ethyl-2-naphthyl ether, N-methyldiphenylamine, 4-isopropylbiphenyl, a,a-dichlorodiphenylmethane, 4-(3-phenylpropyl) pyridine, benzyl benzoate, 1,1-bis (3,4-dimethylphenyl) ethane, 2-isopropylnaphthalene, dibenzyl ether, etc.

In some embodiments, the suitable and preferred solvents are aliphatics, alicyclics, aromatics, amines, thiols, amides, nitriles, esters, ethers, or polyethers.

The solvent may be a cycloalkane, such as decahydronaphthalene. In some embodiments, the formulation as described herein comprises at least 50 wt % of an alcoholic solvent; preferably at least 80 wt %; particularly preferably at least 90 wt %.

In some embodiments, the organic solvent particularly suitable for the present disclosure is a solvent having Hansen solubility parameters in the following ranges:

δ_{d} (dispersion force) is in the range of 17.0 MPa^{1/2} to 23.2 MPa^{1/2}, especially in the range of 18.5 MPa^{1/2} to 21.0 MPa^{1/2};

δₚ (polarity force) is in the range of 0.2 MPa^{1/2} to 12.5 MPa^{1/2}, especially in the range of 2.0 MPa^{1/2} to 6.0 MPa^{1/2};

δₕ (hydrogen bonding force) is in the range of 0.9 MPa^{1/2} to 14.2 MPa^{1/2}, especially in the range of 2.0 MPa^{1/2} to 6.0 MPa^{1/2}.

In the formulation as described herein, the boiling point parameter should be taken into account when selecting the organic solvents. As used herein, the boiling points of the organic solvents ≥150° C.; preferably ≥180° C.; more preferably ≥200° C.; further preferably ≥250° C.; and most preferably ≥275° C. or ≥300° C. The boiling points in these ranges are beneficial in terms for preventing nozzle clogging of the inkjet printhead. The organic solvent can be evaporated from solution system to form a functional film.

In some embodiments, in the formulation as described herein,
1) the viscosity is in the range of 1 cps to 100 cps at 25° C.; and/or
2) the surface tension is in the range of 19 dyne/cm to 50 dyne/cm at 25° C.

In the formulation as described herein, the surface tension parameter should be taken into account when selecting the resins (prepolymers) or the organic solvents. The suitable surface tension parameters of the inks are suitable for the particular substrate and particular printing method. For example, for the ink-jet printing, in some embodiments, the surface tension of the resin (prepolymer) or the organic solvent at 25° C. is in the range of 19 dyne/cm to 50 dyne/cm, more preferably in the range of 22 dyne/cm to 35 dyne/cm, and most preferably in the range of 25 dyne/cm to 33 dyne/cm.

In some embodiments, the surface tension of the formulation at 25° C. is in the range of 19 dyne/cm to 50 dyne/cm; more preferably in the range of 22 dyne/cm to 35 dyne/cm; and most preferably in the range of 25 dyne/cm to 33 dyne/cm.

In the formulation as described herein, the viscosity parameters of the ink should be taken into account when selecting the resins (prepolymers) or the organic solvents. The viscosity can be adjusted by election different methods, such as by the suitable resin (prepolymer) or organic solvent and the concentration of functional materials in the ink. In some embodiments, the viscosity of the resin (prepolymer) or the organic solvent is less than 100 cps, more preferably less than 50 cps, and most preferably from 1.5 cps to 20 cps. The viscosity herein refers to the viscosity during printing at the ambient temperature that is generally at 15-30° C., preferably at 18-28° C., more preferably at 20-25° C., and most preferably at 23-25° C. The resulting formulation will be particularly suitable for ink-jet printing.

In some embodiments, the viscosity of the formulation at 25° C. is in the range of about 1 cps to 100 cps; more preferably in the range of 1 cps to 50 cps; and most preferably in the range of 1.5 cps to 20 cps.

The ink obtained from the resin (prepolymer) or the organic solvent satisfying the above-mentioned boiling point parameter, surface tension parameter and viscosity parameter can form a functional film with uniform thickness and formulation property.

In yet another aspect, the present disclosure further provides an organic functional film comprising a mixture or a formulation as described herein.

In yet another aspect, the present disclosure further provides a method for preparing the organic functional film, as shown in the following steps:
1) prepare a mixture or a formulation as described herein;
2) the mixture or the formulation is coated on a substrate by printing or coating to form a film, where the method of printing or coating is selected from the group consisting of ink-jet printing, nozzle printing, typographic printing, screen printing, dip coating, spin coating, blade coating, roller printing, torsional roll printing, planographic printing, flexographic printing, rotary printing, spray coating, brush or pad printing, and slit die coating;
3) the obtained film is heated at 50° C. and above, optionally in combination with ultraviolet irradiation, to allow the film to undergo a crosslinking reaction and be cured.

The thickness of the organic functional film is generally from 50 nm to 200 m, preferably from 100 nm to 150 m, more preferably from 500 nm to 100 m, further preferably from 1 m to 50 m, and most preferably from 1 m to 20 m.

In yet another aspect, the present disclosure further provides the use of the mixture and the organic functional film in optoelectronic devices.

In some embodiments, the optoelectronic device may be selected from an organic light emitting diode (OLED), an organic photovoltaic cell (OPV), an organic light emitting electrochemical cell (OLEEC), an organic light emitting field effect transistor, or an organic laser.

In yet another aspect, the present disclosure further provides an optoelectronic device comprising a mixture or an organic functional film as described herein.

Preferably, the optoelectronic device is an electroluminescent device, such as an organic light emitting diode (OLED), an organic light emitting electrochemical cell (OLEEC), an organic light emitting field effect transistor, a perovskite light emitting diode (PeLED), or a quantum dot light emitting diode (QD-LED), where one of the functional layers comprises an organic functional film as described herein. The functional layer may be selected from a hole-injection layer, a hole-transport layer, an electron-injection layer, an electron-transport layer, a light-emitting layer, or a cathodic passivation layer (CPL).

In some embodiments, the optoelectronic device is an electroluminescent device comprising two electrodes, where the functional layer is located on the same side of the two electrodes.

In some embodiments, the optoelectronic device comprises a light emitting unit and a color conversion layer (functional layer), where the color conversion layer comprises a mixture or an organic functional film as described herein.

In some embodiments, the color conversion layer absorbs 95% or more of the light from the light emitting unit, preferably 97% or more, more preferably 99% or more, and most preferably 99.9% or more.

In some embodiments, the light emitting unit is selected from a solid-state light emitting device. The solid-state light emitting device is preferably selected from a LED, an organic light emitting diode (OLED), an organic light emitting electrochemical cell (OLEEC), an organic light emitting field effect transistor, a perovskite light emitting diode (PeLED), a quantum dot light emitting diode (QD-LED), or a nanorod LED (see DOI: 10.1038/srep28312).

In some embodiments, the light emitting unit emits blue light, which is converted into green light or red light by the color conversion layer.

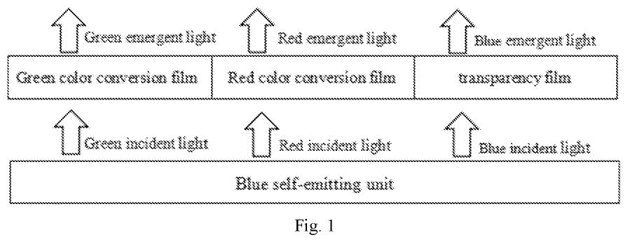

In yet another aspect, the present disclosure further provides a display comprising at least three pixels of red, green and blue. As shown in the attached FIG. 1, the blue pixel comprises a blue emitting unit, and the pixel of red or green comprises a blue emitting unit and a corresponding red or green color conversion layer.

In yet another aspect, the present disclosure further provides an organic light-emitting device comprising a substrate, a first electrode, an organic light-emitting layer, a second electrode, a color conversion layer, and an encapsulation layer in sequence from bottom to top, the second electrode is at least partially transparent, where 1) the color conversion layer comprises the mixture as described herein; 2) the color conversion layer absorbs 50% or more of the light emitted by the organic light-emitting layer through the second electrode; 3) the emission spectrum of the organic compound H is on the short wavelength side of the absorption spectrum of the inorganic nanoemitter E, and at least partially overlaps with the absorption spectrum of the inorganic nanoemitter E; 4) the FWHM of the emission spectrum of the inorganic nanoemitter E≤45 nm.

The organic compound H, the inorganic nanoemitter E, and the preferred embodiment thereof are as described herein.

In some embodiments, the color conversion layer further comprises a resin or a resin prepolymer. The suitable and preferred resins or resin prepolymers are as described herein.

In some embodiments, the object is to obtain a multi-color light, the color conversion layer can absorb 30% or more of the light emitted by the organic light-emitting layer through the second electrode, preferably 40% or more, and most preferably 45% or more.

In some embodiments, the object is to obtain a monochromatic light, the color conversion layer can absorb 90% or more of the light emitted by the organic light-emitting layer through the second electrode, preferably 95% or more, more preferably 99% or more, and most preferably 99.9% or more.

In some embodiments, the thickness of the color conversion layer is between 100 nm and 5 m, preferably between 150 nm and 4 m, more preferably between 200 nm and 3 m, and most preferably between 200 nm and 2 m.

In some embodiments, the organic light-emitting device is an OLED. More preferably, the first electrode is an anode, the second electrode is a cathode. Particularly preferably, the organic light-emitting device is a top emission OLED.

The substrate should be opaque or transparent. A transparent substrate could be used to produce a transparent light-emitting device (for example: Bulovic et al. , Nature 1996, 380, p29, and Gu et al. , Appl. Phys. Lett. 1996, 68, p2606). Substrate may be either rigid or elastic. The substrate can be rigid/flexible, e.g. it can be plastic, metal, semiconductor wafer, or glass. Preferably, the substrate has a smooth surface. Particularly desirable are substrates without surface defects. In some embodiments, the substrate is flexible and can be selected from a polymer film or plastic with a glass transition temperature (Tg) >150° C., preferably >200° C., more preferably >250° C., and most preferably >300° C. Examples of the suitable flexible substrate includes poly (ethylene terephthalate) (PET) and polyethylene glycol (2,6-naphthalene) (PEN).

The choice of anodes may include a conductive metal, or a metal oxide, or a conductive polymer. The anode should be able to easily inject holes into a hole-injection layer (HIL), a hole-transport layer (HTL), or a light-emitting layer. In some embodiments, the absolute value of the difference between the work function of the anode and the HOMO energy level of the emitter of the light-emitting layer, or the HOMO energy level/valence band energy level of the p-type semiconductor materials of the hole-injection layer (HIL)/hole-transport layer (HTL)/electron-blocking layer (EBL) <0.5 eV, preferably <0.3 eV, more preferably <0.2 eV. Examples of anode materials may include, but not limited to: Al, Cu, Au, Ag, Mg, Fe, Co, Ni, Mn, Pd, Pt, ITO, aluminum-doped zinc oxide (AZO), etc. Other suitable anode materials are known and can be readily selected for use by the general technicians in this field. The anode material can be deposited using any suitable technique, such as a suitable physical vapor deposition method, including RF magnetron sputtering, vacuum thermal evaporation, e-beam, etc. In some embodiments, the anode is patterned. Patterned conductive ITO substrates are commercially available and can be used to produce the devices as described herein.

The choice of cathode may include a conductive metal or a metal oxide. The cathode should be able to easily inject electrons into the EIL, the ETL, or the directly into the light-emitting layer. In some embodiments, the absolute value of the difference between the work function of the cathode and the LUMO energy level of the emitter of the light-emitting layer, or the LUMO energy level/conduction band energy level of the n-type semiconductor materials of the electron-injection layer (EIL)/electron-transport layer (ETL)/hole-blocking layer (HBL) <0.5 eV, preferably <0.3 eV, and most preferably <0.2 eV. In principle, all materials that can be used as cathodes for OLEDs may be applied as cathode materials for the devices as described herein. Examples of cathode materials include, but not limited to: Al, Au, Ag, Ca, Ba, Mg, LiF/Al, MgAg alloys, BaF₂/Al, Cu, Fe, Co, Ni, Mn, Pd, Pt, ITO, etc. The cathode materials can be deposited using any suitable technique, such as the suitable physical vapor deposition method, including RF magnetron sputtering, vacuum thermal evaporation, e-beam, etc. In some embodiments, the transmittance of the cathode in the range of 400-680 nm≥40%, preferably ≥45%, more preferably ≥50%, and most preferably ≥60%. Typically, 10-20 nm of Mg:Ag alloys can be used as transparent cathodes, and the ratio of the Mg:Ag can range from 2:8 to 0.5:9.5.

The light-emitting layer of the organic light-emitting device preferably comprises a blue fluorescent host and a blue fluorescent dopant. In some embodiments, the light-emitting layer comprises a blue phosphorescent host and a blue phosphorescent dopant. The OLED may also comprise other functional layers, such as a hole-injection layer (HIL), a hole-transport layer (HTL), an electron-blocking layer (EBL), an electron-injection layer (EIL), an electron-transport layer (ETL), and a hole-blocking layer (HBL). Materials suitable for use in these functional layers are described in details above and in WO2010135519A1, US20090134784A1, and WO2011110277A1, the entire contents of these three documents are hereby incorporated herein for reference.

Further, the organic light-emitting device further comprises a cathode capping layer (CPL).

In some embodiments, the CPL is disposed between the second electrode and the color conversion layer.

In some embodiments, the CPL is disposed on the top of the color conversion layer.

The CPL material generally requires high refractive index (n), such as n≥1.95@460 nm, n≥1.90@520 nm, n≥1.85@620 nm. Examples of the CPL materials include:

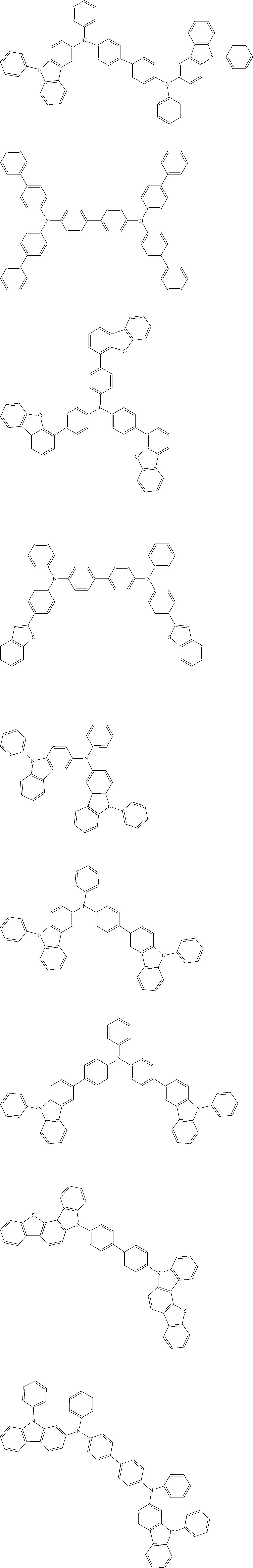

More further examples of the CPL materials can be found in the following patent literature: KR20140128653A, KR20140137231A, KR20140142021A, KR20140142923A, KR20140143618A, KR20140145370A, KR20150004099A, KR20150012835A, U.S. Pat. No. 9,496,520B2, US2015069350A1, CN103828485B , CN104380842B , CN105576143A, TW201506128A, CN103996794A, CN103996795A, CN104744450A, CN104752619A, CN101944570A, US2016308162A1, U.S. Pat. No. 9,095,033B2, US2014034942A1, WO2017014357A1. The above patent documents are incorporated herein by reference in their entirety.

In some embodiments, the color conversion layer comprises a CPL material as described above.

Preferably, the encapsulation layer of the organic light-emitting device is thin-film encapsulated (TFE).

In yet another aspect, The present disclosure further provides a display panel, where at least one pixel comprises an organic light-emitting device as described herein.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### Specific Embodiment

The organic compound H as the host material comprises a structure shown in H1-H14:

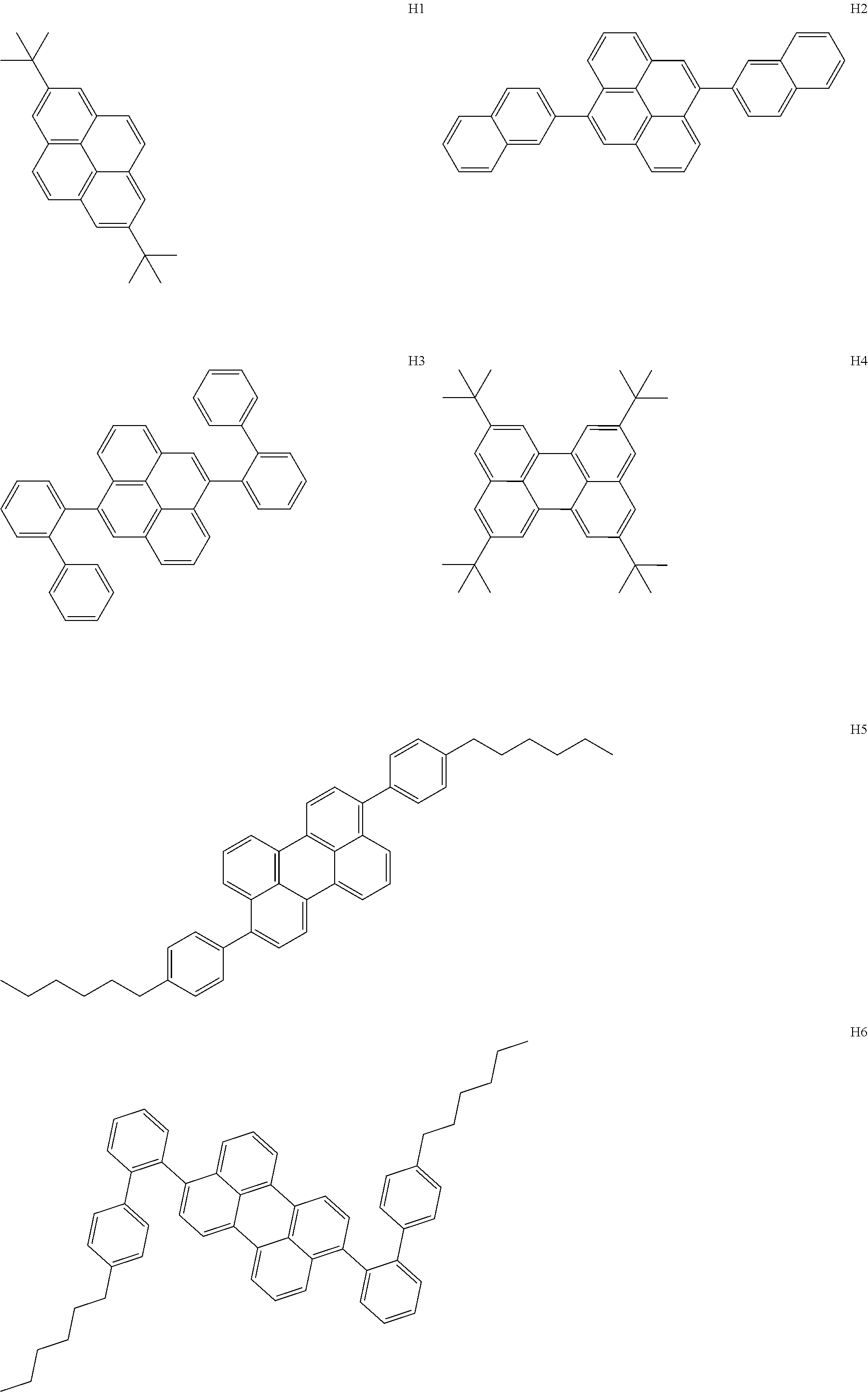

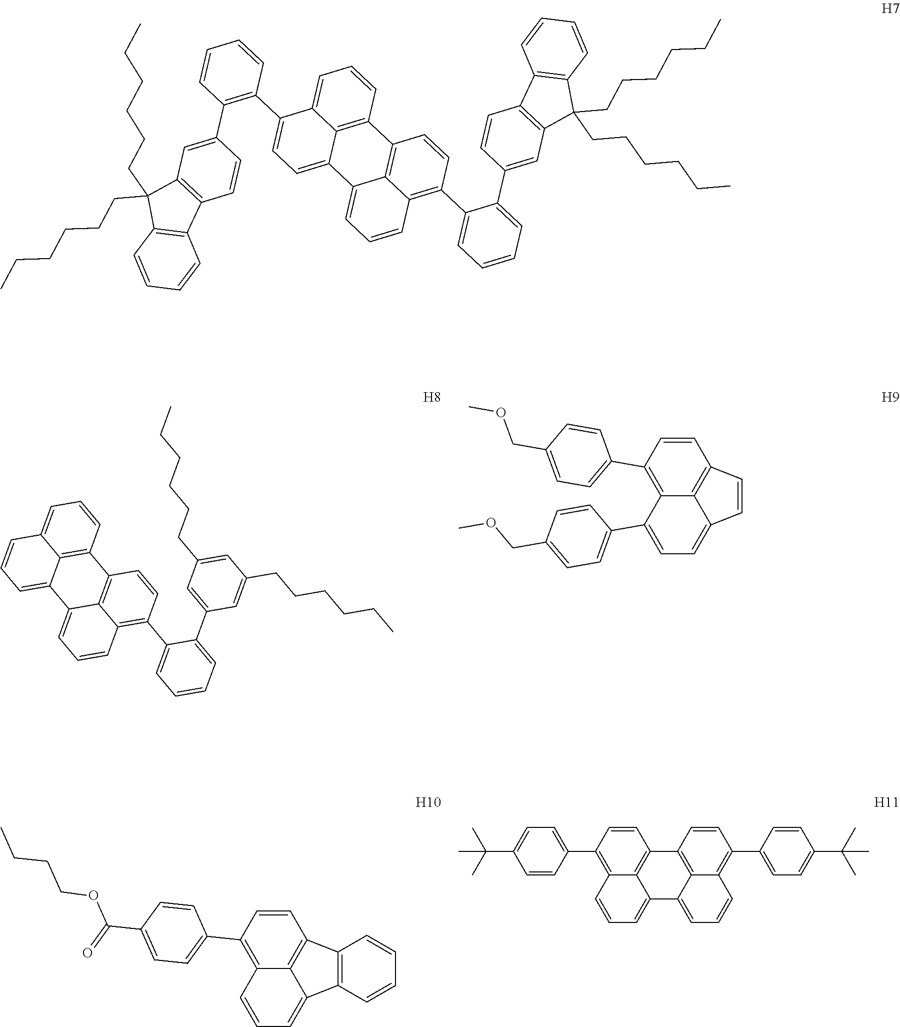

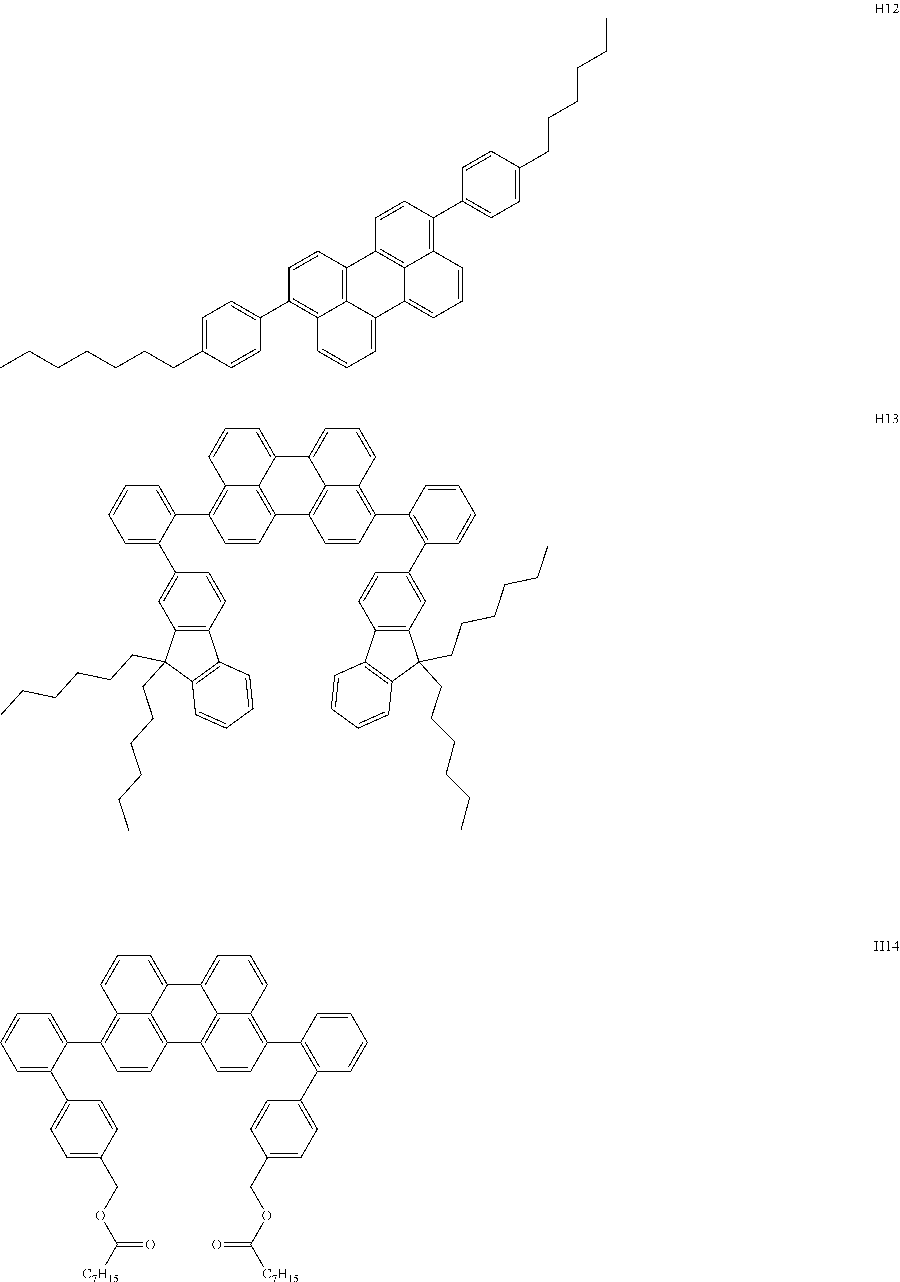

The synthesis of the host materials (H1-H14) were as disclosed in the contemporaneous patent application with application No. CN202110370887.3.

A green quantum dot (QD1) as the green emitter E was purchased from Hefei Funa Technology Co., Ltd.

### Example 1

### Preparation of Polymers-Containing Formulations and Organic Functional Films

100 mg of polymethyl methacrylate (PMMA), 50 mg of the host material (H1-H14) for color conversion, and 5 mg of the inorganic nanoemitter E (i.e., a green quantum dot QD1) were dissolved in 1 mL of n-butyl acetate to obtain a clear solution (i.e., a formulation or a printing ink). Using a KW-4a spin coater, the above clear solution was spun-coated on the surface of the quartz glass to form an uniform thin film, which is an organic functional film (i.e., a color conversion film). When the thickness is thinner than 6 μm, most of the obtained color conversion films have an optical density (OD) reach 3 or more.

### Example 2

### Preparation of Resin Prepolymers-Containing Formulations and Organic Functional Films

The resin prepolymers-containing formulations and organic functional films could be obtained that the above-mentioned host materials (H1-H14) for color conversion and green quantum dots (QD1) were premixed with resin prepolymer (such as methyl methacrylate, styrene, or methylstyrene). Initiated by 1-5 wt % of a photoinitiator (such as TPO (diphenyl (2,4,6-trimethylbenzoyl) phosphine oxide, 97%, CAS: 75980-60-8), the obtained formulation could form a thin film by spin coating, coating method, etc., and the obtained film was further cured by irradiation with a 365 nm or 390 nm UV LED lamp to form a color conversion film.

The green color conversion film can be disposed in a blue self-emitting unit that exhibits blue emission in the range of 400 nm to 490 nm. Through the green color converter, the blue light could change to a green light ranging from 490 nm to 550 nm.

### Example 3

### Preparation of Top-Emission OLED Devices

Materials to be used in the preparation of the top-emission OLED devices:

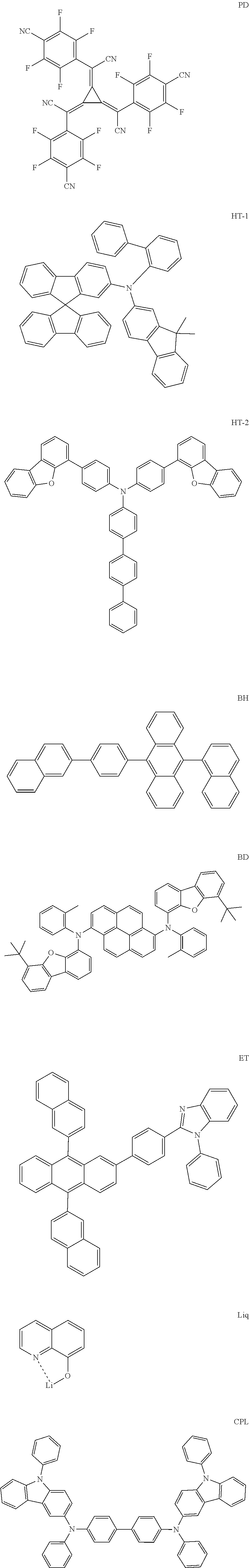

Preparation of Ink1:

Preparation of prepolymers: n-butyl acetate (42 wt %), methyl methacrylate (MMA) (50 wt %), hydroxypropyl acrylate (HPA) (3 wt %), and benzoyl peroxide (BPO) (5 wt %) were respectively weighed, mixed and stirred for 50 minutes at 125° C. to obtain a prepolymer. The prepolymer (67 wt %), n-butyl acetate (30 wt %), host material (H13) (2.5 wt %) for color conversion and inorganic nanoemitter E (i.e., green quantum dot QD1) (0.5 wt %) were mixed and stirred to obtain a clear solution (Ink1).

Preparation of Ink2:

50 mg of host material (H13) for color conversion and 10 mg of inorganic nanoemitter E (i.e., green quantum dot QD1) were dissolved in 1 mL of n-butyl acetate to obtain a clear solution (Ink2).

1. Green Light-Emitting Device 1
a. Cleaning of Ag-containing ITO (indium tin oxide) top substrate: the substrate was ultrasonically cleaned with strip liquid, pure water, and isopropyl alcohol in sequence, then treated with ozone in argon after drying.
b. Evaporation: the resultant substrate was mounted on a vacuum deposition apparatus in high vacuum (1×10⁻⁶ mbar), the weight ratio of PD and HT-1 was controlled to be 3:100 to form a hole-injection layer (HIL) having a thickness of 10 nm, followed by evaporation of compound HT-1 on the hole-injection layer to form a hole-transport layer (HTL) having a thickness of 120 nm, and then immediately followed by evaporation of compound HT-2 on the hole-transport layer to form a hole-buffer layer having a thickness of 10 nm. Then BH and BD at a weight ratio of 100:3 to form a light-emitting layer film having a thickness of 25 nm. Subsequently, ET and Liq were respectively placed in two different evaporation sources, and co-deposited on the light-emitting layer at a weight ratio of 50:50 to form an electron-transport layer having a thickness of 35nm. Yb was then deposited on the electron-transport layer to form an electron-injection layer having a thickness of 1.5 nm and Mg:Ag (1:9) alloy was deposited on the electron-injection layer to form a cathode having a thickness of 16 nm.
c. On the cathode, inkl was printed with Haisi electronic IJDAS310 (nozzle FUJIFILM Dimatix DMC-11610), then cured by irradiation with a 390 nm UV LED lamp to obtain a color conversion layer with a thickness of 2 m to 3 m.
d. Encapsulation: encapsulating the device in a nitrogen-regulated glove box with UV curable resin.

2. Green light-emitting device 2: steps a, b, d are the same as described in the procedure for preparing the above-mentioned green light-emitting device 1, the step c is as follows:
c. On the cathode, ink2 was printed with Haisi Electronic IJDAS310 (nozzle FUJIFILM Dimatix DMC-11610) to obtain a color conversion layer with a thickness of 1 m to 2 m.

3. Green light-emitting device 3: steps a, b, c are the same as described in the procedure for preparing the above-mentioned green light emitting device 1, the steps d, e are as follows:
d. CPL with a thickness of 70 nm was evaporated on the color conversion layer and used as an optical capping layer.
e. Encapsulation: encapsulating the device in a nitrogen-regulated glove box with UV curable resin.

4. Green light-emitting device 4: steps a, b, c are the same described in the procedure for preparing as the above-mentioned green light-emitting device 2, the steps d, e are as follows:
d. CPL with a thickness of 70 nm was evaporated on the color conversion layer and used as an optical capping layer.
e. Encapsulation: encapsulating the device in a nitrogen-regulated glove box with UV curable resin.

All of the above green light emitting devices 1-4 have high color purity, and the FWHMs of their emission spectrums are below 30 nm.

The technical features of the above-described embodiments can be combined in any ways. For the sake of brevity, not all possible combinations of the technical features of the above-described embodiments have been described. However, as long as there are no contradictions in the combination of these technical features, they should be considered to be within the scope of this specification.

What described above are several embodiments of the present disclosure, and they are specific and in detail, but not intended to limit the scope of the present disclosure. It will be understood that improvements can be made without departing from the concept of the present disclosure, and all these modifications and improvements are within the scope of the present disclosure. The scope of the present disclosure shall be subject to the appended claims.

What is claimed is:

1. A mixture, comprising an organic compound H, an inorganic nanoemitter E, and at least one organic resin, wherein an emission spectrum of the organic compound H is on a short wavelength side of an absorption spectrum of the inorganic nanoemitter E, and at least partially overlaps with the absorption spectrum of the inorganic nanoemitter E; and a full width at half maximum (FWHM) of an emission spectrum of the inorganic nanoemitter E≤45 nm.

2. The mixture according to claim 1, wherein the inorganic nanoemitter E is selected from a colloidal quantum dot or a nanorod with a single distribution.

3. The mixture according to claim 2, wherein the inorganic nanoemitter E comprises a semiconductor material, selecting from CdSe, CdS, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AN, AlAs, AlSb, CdSeTe, ZnCdSe, PbSe, PbTe, PbS, PbSnTe, Tl₂SnTes, or any combination thereof.

4. The mixture according to claim 3, wherein the inorganic nanoemitter E is a heterostructure comprising two different semiconductors, and the heterostructure is a core/shell structure with at least one shell.

5. The mixture according to claim 1, wherein the organic compound H is selected from the compound comprising at least one of the following groups: 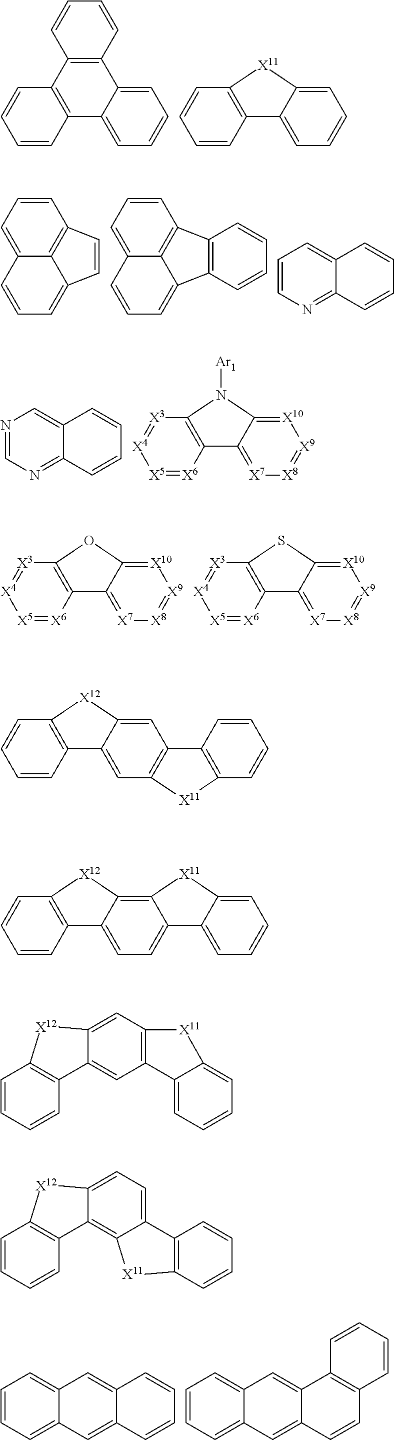 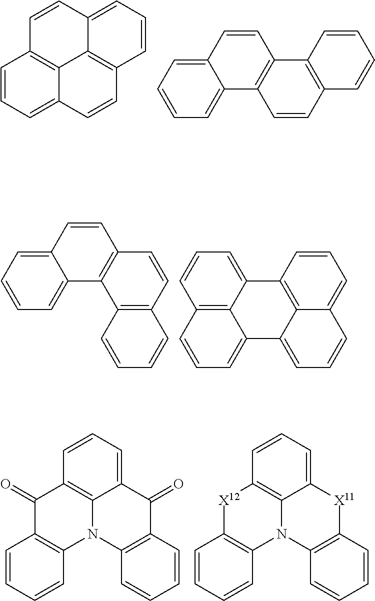
wherein, Ar₁ is aryl or heteroaryl; each of X³ to X¹⁰ is CR¹ or N; X¹¹ and X¹² are independently selected from CR¹R², NR¹, or O;
R¹ and R² are independently selected from the group consisting of —H, —D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂o branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, and a disubstituted unit in any position of the above substituents or a combination thereof, wherein one or more R¹-R² form a monocyclic or polycyclic aliphatic or aromatic ring system with each other and/or with the rings bonded thereto.

6. The mixture according to claim 1, wherein at least one of the organic resin is a thermosetting resin or a UV curable resin.

7. The mixture according to claim 6, wherein the weight ratio of the at least one of the organic resin is from 20 wt % to 99 wt %.

8. A formulation, comprising the mixture according to claim 1, and at least one solvent.

9. The formulation according to claim 8, wherein at least one of the solvent is selected from water, alcohols, esters, aromatic ketones, aromatic ethers, aliphatic ketones, aliphatic ethers, borates, phosphorates, or mixtures of two or more of them.

10. An organic light-emitting device, comprising a substrate, a first electrode, an organic light-emitting layer, a second electrode, a color conversion layer, and an encapsulation layer in sequence from bottom to top, wherein the second electrode is at least partially transparent, the color conversion layer comprises the mixture according to claim 1; the color conversion layer absorbs 50% or more of the light emitted by the organic light-emitting layer through the second electrode; the emission spectrum of the organic compound H is on the short wavelength side of the absorption spectrum of the inorganic nanoemitter E, and at least partially overlaps with the absorption spectrum of the inorganic nanoemitter E; and the FWHM of the emission spectrum of the inorganic nanoemitter E≤45 nm.

11. The organic light-emitting device according to claim 10, wherein the inorganic nanoemitter E is selected from a colloidal quantum dot or a nanorod with a single distribution.
